(19) United States
(12) Patent Application Publication
(10) Pub. No.: US 2025/0015089 A1
(43) Pub. Date: Jan. 9, 2025

(54) Semiconductor Device

(71) Applicant: Semiconductor Energy Laboratory Co., Ltd., Kanagawa-ken (JP)

(72) Inventors: Shunpei YAMAZAKI, Setagaya, Tokyo (JP); Hitoshi KUNITAKE, Machida, Tokyo (JP); Ryota HODO, Atsugi, Kanagawa (JP); Tsutomu MURAKAWA, Isehara, Kanagawa (JP)

(73) Assignee: Semiconductor Energy Laboratory Co., Ltd., Kanagawa-ken (JP)

(21) Appl. No.: 18/712,398

(22) PCT Filed: Nov. 17, 2022
(86) PCT No.: PCT/IB2022/061048

§ 371 Date: May 22, 2024

(30) Foreign Application Priority Data
Nov. 26, 2021 (JP) 2021-191981

(51) Int. Cl. H01L 27/12

(52) U.S. Cl. CPC H01L 27/1225

(57) ABSTRACT

A semiconductor device that can be miniaturized or highly integrated is provided. The semiconductor device includes a first insulator, a first metal oxide, a first conductor, a second conductor, and a third conductor. The first metal oxide includes a first depressed portion, a second depressed portion, and a third depressed portion positioned between the first depressed portion and the second depressed portion. The first conductor is provided to fill the first depressed portion, and the second conductor is provided to fill the second depressed portion. A top surface of the first conductor and a top surface of the second conductor are level with or substantially level with a top surface of the first metal oxide. The first insulator is provided inside the third depressed portion. The third conductor is provided over the first insulator and includes a region overlapping with the first metal oxide with the first insulator therebetween.

### TECHNICAL FIELD

One embodiment of the present invention relates to a transistor, a semiconductor device, and an electronic appliance. Another embodiment of the present invention relates to a method for manufacturing a semiconductor device. Another embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a storage device that can retain stored contents for a long time by utilizing a feature of a low leakage current of the transistor using an oxide semiconductor.

In recent years, demand for an integrated circuit with higher density has risen with reductions in size and weight of electronic appliances. Furthermore, the productivity of a semiconductor device including an integrated circuit is desired to be improved.

### REFERENCE

### Patent Document

[Patent Document 1] Japanese Published Patent Application No. 2012-257187
[Patent Document 2] Japanese Published Patent Application No. 2011-151383

### SUMMARY OF THE INVENTION

### Problems to be Solved by the Invention

An object of one embodiment of the present invention is to provide a semiconductor device that can be miniaturized or highly integrated. An object of one embodiment of the present invention is to provide a semiconductor device with favorable electrical characteristics. An object of one embodiment of the present invention is to provide a semiconductor device with a small variation in electrical characteristics of transistors. An object of one embodiment of the present invention is to provide a semiconductor device with favorable reliability. An object of one embodiment of the present invention is to provide a semiconductor device with a high on-state current. An object of one embodiment of the present invention is to provide a semiconductor device with low power consumption.

Note that the description of these objects does not preclude the existence of other objects. One embodiment of the present invention does not need to achieve all these objects. Other objects will be apparent from the description of the specification, the drawings, the claims, and the like, and other objects can be derived from the description of the specification, the drawings, the claims, and the like.

### Means for Solving the Problems

One embodiment of the present invention is a semiconductor device including a first insulator, a first metal oxide, a first conductor, a second conductor, and a third conductor. The first metal oxide includes a first depressed portion, a second depressed portion, and a third depressed portion positioned between the first depressed portion and the second depressed portion. The first conductor is provided to fill the first depressed portion, and the second conductor is provided to fill the second depressed portion. A top surface of the first conductor and a top surface of the second conductor are each level with or substantially level with a top surface of the first metal oxide. The first insulator is provided inside the third depressed portion. The third conductor is provided over the first insulator and includes a region overlapping with the first metal oxide with the first insulator therebetween.

Another embodiment of the present invention is a semiconductor device including a first insulator, a second insulator, a third insulator, a fourth insulator, a first metal oxide, a second metal oxide, a first conductor, a second conductor, and a third conductor. The first metal oxide, the fourth insulator, and the second metal oxide are provided over the second insulator. The fourth insulator is positioned between the first metal oxide and the second metal oxide in a top view. A top surface of the first metal oxide and a top surface of the second metal oxide are each level with or substantially level with a top surface of the fourth insulator. The third insulator is provided over the first metal oxide, the fourth insulator, and the second metal oxide. The first metal oxide includes a first depressed portion, a second depressed portion, and a third depressed portion positioned between the first depressed portion and the second depressed portion. The first conductor is provided to fill the first depressed portion, and the second conductor is provided to fill the second depressed portion. A top surface of the first conductor and a top surface of the second conductor are each level with or substantially level with a top surface of the first metal oxide. The third insulator includes an opening portion overlapping with the third depressed portion. The first insulator is provided in the third depressed portion and inside the opening portion. The third conductor is provided over the first insulator and includes a region overlapping with the first metal oxide with the first insulator therebetween.

In the above semiconductor device, it is preferable that a bottom surface of the first depressed portion be positioned closer to a bottom surface side of the first metal oxide than a bottom surface of the third depressed portion, and a bottom surface of the second depressed portion be positioned closer to a bottom surface side of the first metal oxide than the bottom surface of the third depressed portion.

Alternatively, in the above semiconductor device, it is preferable that a bottom surface of the first depressed portion be level with or substantially level with a bottom surface of the third depressed portion, and a bottom surface of the second depressed portion be level with or substantially level with the bottom surface of the third depressed portion.

Alternatively, in the above semiconductor device, it is preferable that a bottom surface of the first depressed portion be positioned closer to a top surface side of the first metal oxide than a bottom surface of the third depressed portion, and a bottom surface of the second depressed portion be positioned closer to a top surface side of the first metal oxide than the bottom surface of the third depressed portion.

Another embodiment of the present invention is a semiconductor device including a first insulator, a second insulator, a third insulator, a metal oxide, a first conductor, a second conductor, and a third conductor. The metal oxide and the third insulator are provided over the second insulator. The metal oxide is surrounded by the third insulator in a top view. A top surface of the metal oxide is level with or substantially level with a top surface of the third insulator. The metal oxide includes a first depressed portion, a second depressed portion, and a third depressed portion positioned between the first depressed portion and the second depressed portion. The first conductor is provided to fill the first depressed portion, and the second conductor is provided to fill the second depressed portion. A top surface of the first conductor and a top surface of the second conductor are each level with or substantially level with the top surface of the metal oxide. The first insulator is provided inside the third depressed portion. The third conductor is provided over the first insulator and includes a region overlapping with the metal oxide with the first insulator therebetween.

### Effect of the Invention

According to one embodiment of the present invention, a semiconductor device that can be miniaturized or highly integrated can be provided. According to another embodiment of the present invention, a semiconductor device with high reliability can be provided. According to another embodiment of the present invention, a semiconductor device with a small variation in electrical characteristics of transistors can be provided. According to another embodiment of the present invention, a semiconductor device with favorable electrical characteristics can be provided. According to another embodiment of the present invention, a semiconductor device with a high on-state current can be provided. According to another embodiment of the present invention, a semiconductor device with low power consumption can be provided.

Note that the description of these effects does not preclude the existence of other effects. One embodiment of the present invention does not have to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a top view of a semiconductor device of one embodiment of the present invention.

FIG. 1B to FIG. 1D are cross-sectional views of the semiconductor device of one embodiment of the present invention.

FIG. 2 is a cross-sectional view of a semiconductor device of one embodiment of the present invention.

FIG. 3A and FIG. 3B are cross-sectional views of a semiconductor device of one embodiment of the present invention.

FIG. 4A, FIG. 4C, and FIG. 4E are top views of a semiconductor device of one embodiment of the present invention. FIG. 4B, FIG. 4D, and FIG. 4F are cross-sectional views of the semiconductor device of one embodiment of the present invention.

FIG. 5 is a cross-sectional view of a semiconductor device of one embodiment of the present invention.

FIG. 6A is a top view of a semiconductor device of one embodiment of the present invention.

FIG. 6B and FIG. 6C are cross-sectional views of the semiconductor device of one embodiment of the present invention.

FIG. 7A to FIG. 7C are top views of a semiconductor device of one embodiment of the present invention.

FIG. 8A is a top view of a semiconductor device of one embodiment of the present invention.

FIG. 8B to FIG. 8D are cross-sectional views of the semiconductor device of one embodiment of the present invention.

FIG. 9A is a top view of a semiconductor device of one embodiment of the present invention.

FIG. 9B to FIG. 9D are cross-sectional views of the semiconductor device of one embodiment of the present invention.

FIG. 10A is a top view of a semiconductor device of one embodiment of the present invention.

FIG. 10B to FIG. 10D are cross-sectional views of the semiconductor device of one embodiment of the present invention.

FIG. 11A is a top view of a semiconductor device of one embodiment of the present invention.

FIG. 11B to FIG. 11D are cross-sectional views of the semiconductor device of one embodiment of the present invention.

FIG. 12A is a top view illustrating a method for manufacturing a semiconductor device of one embodiment of the present invention. FIG. 12B to FIG. 12D are cross-sectional views illustrating a method for manufacturing the semiconductor device of one embodiment of the present invention.

FIG. 13A is a top view illustrating a method for manufacturing a semiconductor device of one embodiment of the present invention. FIG. 13B to FIG. 13D are cross-sectional views illustrating a method for manufacturing the semiconductor device of one embodiment of the present invention.

FIG. 14A is a top view illustrating a method for manufacturing a semiconductor device of one embodiment of the present invention. FIG. 14B to FIG. 14D are cross-sectional views illustrating a method for manufacturing the semiconductor device of one embodiment of the present invention.

FIG. 15A is a top view illustrating a method for manufacturing a semiconductor device of one embodiment of the present invention. FIG. 15B to FIG. 15D are cross-sectional views illustrating a method for manufacturing the semiconductor device of one embodiment of the present invention.

FIG. 16A is a top view illustrating a method for manufacturing a semiconductor device of one embodiment of the present invention. FIG. 16B to FIG. 16D are cross-sectional views illustrating a method for manufacturing the semiconductor device of one embodiment of the present invention.

FIG. 17A is a top view illustrating a method for manufacturing a semiconductor device of one embodiment of the present invention. FIG. 17B to FIG. 17D are cross-sectional views illustrating a method for manufacturing the semiconductor device of one embodiment of the present invention.

FIG. 18A is a top view illustrating a method for manufacturing a semiconductor device of one embodiment of the present invention. FIG. 18B to FIG. 18D are cross-sectional views illustrating a method for manufacturing the semiconductor device of one embodiment of the present invention.

FIG. 19A is a top view illustrating a method for manufacturing a semiconductor device of one embodiment of the present invention. FIG. 19B to FIG. 19D are cross-sectional views illustrating a method for manufacturing the semiconductor device of one embodiment of the present invention.

FIG. 20A is a top view illustrating a method for manufacturing a semiconductor device of one embodiment of the present invention. FIG. 20B to FIG. 20D are cross-sectional views illustrating a method for manufacturing the semiconductor device of one embodiment of the present invention.

FIG. 21A is a top view illustrating a method for manufacturing a semiconductor device of one embodiment of the present invention. FIG. 21B to FIG. 21D are cross-sectional views illustrating a method for manufacturing the semiconductor device of one embodiment of the present invention.

FIG. 22A is a top view illustrating a method for manufacturing a semiconductor device of one embodiment of the present invention. FIG. 22B to FIG. 22D are cross-sectional views illustrating a method for manufacturing the semiconductor device of one embodiment of the present invention.

FIG. 23 is a top view illustrating a microwave treatment apparatus of one embodiment of the present invention.

FIG. 24 is a schematic cross-sectional view illustrating a microwave treatment apparatus of one embodiment of the present invention.

FIG. 25 is a schematic cross-sectional view illustrating a microwave treatment apparatus of one embodiment of the present invention.

FIG. 26 is a schematic view illustrating a microwave treatment apparatus of one embodiment of the present invention.

FIG. 27A is a top view of a semiconductor device of one embodiment of the present invention.

FIG. 27B and FIG. 27C are cross-sectional views of the semiconductor device of one embodiment of the present invention.

FIG. 28 is a cross-sectional view illustrating a structure of a storage device of one embodiment of the present invention.

FIG. 29 is a cross-sectional view illustrating a structure of a storage device of one embodiment of the present invention.

FIG. 30A is a block diagram illustrating a structure example of a storage device of one embodiment of the present invention. FIG. 30B is a perspective view illustrating a structure example of the storage device of one embodiment of the present invention.

FIG. 31A to FIG. 31H are circuit diagrams each illustrating a structure example of a storage device of one embodiment of the present invention.

FIG. 32A and FIG. 32B are schematic views of a semiconductor device of one embodiment of the present invention.

FIG. 33A and FIG. 33B are diagrams illustrating examples of electronic components.

FIG. 34A to FIG. 34E are schematic views of storage devices of one embodiment of the present invention.

FIG. 35A to FIG. 35H are diagrams illustrating electronic appliances of one embodiment of the present invention.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In addition, in the drawings, the size, the layer thickness, or the region is exaggerated for clarity in some cases. Therefore, the size, the layer thickness, or the region is not necessarily limited to the illustrated scale. Note that the drawings schematically illustrate ideal examples, and embodiments of the present invention are not limited to shapes, values, and the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. Furthermore, the same hatching pattern is used for the portions having similar functions, and the portions are not especially denoted by reference numerals in some cases.

Furthermore, especially in a top view (also referred to as a “plan view”), a perspective view, or the like, the description of some components may be omitted for easy understanding of the invention. In addition, some hidden lines may be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relation between components is changed as appropriate in accordance with the direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter, also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, in a transistor whose gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, or the like can be determined, for example, by analyzing a cross-sectional TEM image.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as Vo) are formed in an oxide semiconductor in some cases by entry of impurities, for example.

Note that in this specification and the like, silicon oxynitride is a substance that contains more oxygen than nitrogen in its composition. Moreover, silicon nitride oxide is a substance that contains more nitrogen than oxygen in its composition. Similarly, aluminum oxynitride refers to a substance that contains more oxygen than nitrogen in its composition. Moreover, aluminum nitride oxide refers to a substance that contains more nitrogen than oxygen in its composition. Similarly, hafnium oxynitride refers to a substance that contains more oxygen than nitrogen in its composition. Moreover, hafnium nitride oxide is a substance that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor in the description can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit and the like, and a potential output from a circuit and the like, for example, change with a change of the reference potential.

In this specification and the like, when a plurality of components are denoted with the same reference numerals, and in particular need to be distinguished from each other, an identification sign such as “_1”, “[n]”, or “[m,n]” is sometimes added to the reference numerals.

Note that in this specification and the like, the expression “level or substantially level” indicates a structure having the same level from a reference surface (e.g., a flat surface such as a substrate surface) in a cross-sectional view. For example, in a manufacturing process of the semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level or substantially level” in this specification and the like. For example, the expression “level or substantially level” includes the case where two layers (here, given as a first layer and a second layer) having different two levels with respect to the reference surface are included, and the difference between the top-surface level of the first layer and the top-surface level of the second layer is less than or equal to 20 nm.

Note that in this specification and the like, the expression “end portions are aligned or substantially aligned” means that at least outlines of stacked layers partly overlap with each other in a top view. For example, the case of processing the upper layer and the lower layer with the use of the same mask pattern or mask patterns that are partly the same is included. However, in some cases, the outlines do not exactly overlap with each other and the outline of the upper layer is located inward from the outline of the lower layer or the outline of the upper layer is located outward from the outline of the lower layer; such a case is also represented by the expression “end portions are aligned or substantially aligned”.

In this specification, in the case where the maximum value and the minimum value are specified, a structure in which the maximum value and the minimum value are freely combined is also disclosed.

### Embodiment 1

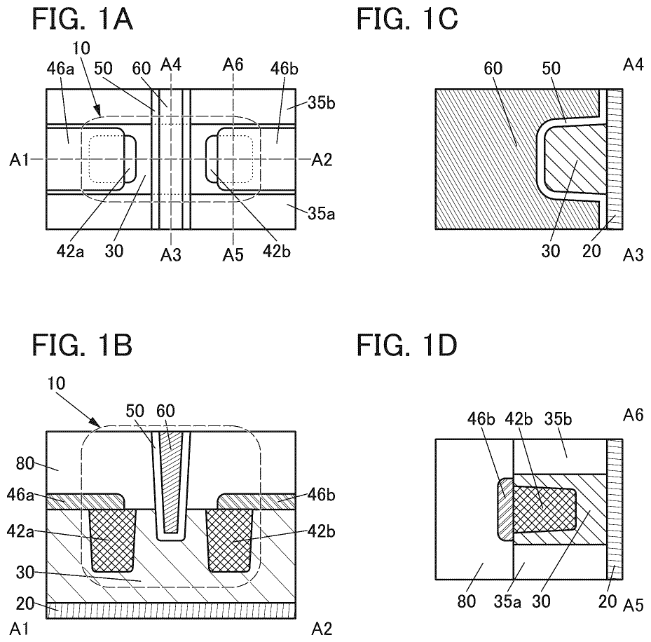

In this embodiment, an example of a semiconductor device of one embodiment of the present invention and a manufacturing method thereof will be described with reference to FIG. 1A to FIG. 27C. The semiconductor device of one embodiment of the present invention includes a transistor.

### Structure Example 1

A structure of a semiconductor device including a transistor 10 is described with reference to FIG. 1A to FIG. 1D. FIG. 1A to FIG. 1D are a top view and cross-sectional views of the semiconductor device including the transistor 10. FIG. 1A is a top view of the semiconductor device. FIG. 1B to FIG. 1D are cross-sectional views of the semiconductor device. Here, FIG. 1B is a cross-sectional view of a portion indicated by the dashed-dotted line A1-A2 in FIG. 1A, and is also a cross-sectional view of the transistor 10 in the channel length direction. FIG. 1C is a cross-sectional view of a portion indicated by the dashed-dotted line A3-A4 in FIG. 1A, and is also a cross-sectional view of the transistor 10 in the channel width direction. FIG. 1D is a cross-sectional view of a portion indicated by the dashed-dotted line A5-A6 in FIG. 1A. Note that for clarity of the drawing, some components are omitted in the top view of FIG. 1A.

### [Transistor 10]

As illustrated in FIG. 1A to FIG. 1D, the transistor 10 includes an oxide 30, a conductor 42a, a conductor 42b, an insulator 50, and a conductor 60.

The oxide 30 includes a first depressed portion, a second depressed portion, and a third depressed portion. Examples of the depressed portion include an opening portion, a groove portion, and a slit portion. In the channel length direction of the transistor 10, the third depressed portion is positioned between the first depressed portion and the second depressed portion. Note that in a cross-sectional view in the channel length direction, the level of the top surface of a region overlapping with the third depressed portion (or the conductor 60) of the oxide 30 is lower than the level of the top surface of a region between the first depressed portion and the third depressed portion of the oxide 30 and the level of the top surface of a region between the second depressed portion and the third depressed portion of the oxide 30. Furthermore, in a cross-sectional view in the channel width direction, a region of the oxide 30 that overlaps with the third depressed portion (or the conductor 60) has a convex upward shape. That is, the third depressed portion can be referred to as a saddle. Note that in the case where the saddle is seen from a certain direction (e.g., a direction in which the conductor 60 extends), the saddle includes a depressed portion; thus, in this specification and the like, a saddle positioned between the first depressed portion and the second depressed portion is referred to as a third depressed portion.

The conductor 42a is provided to fill the first depressed portion of the oxide 30, and the conductor 42b is provided to fill the second depressed portion of the oxide 30. Thus, it can be said that the third depressed portion of the oxide 30 is positioned between the conductor 42a and the conductor 42b in the channel length direction of the transistor 10.

The top surface of the conductor 42a and the top surface of the conductor 42b are each level with or substantially level with the top surface of the oxide 30.

Although the top surface shapes of the conductor 42a and the conductor 42b are each a polygonal shape with rounded corners in FIG. 1A, the top surface shapes are not limited thereto. The top surface shape may be a polygonal shape, an elliptical shape, a circular shape, or the like. Note that although the above polygon is a quadrangle in FIG. 1A, the polygon may be other than a quadrangle such as a triangle or a pentagon. Note that the top surface shape of the first depressed portion of the oxide 30 is the same as the top surface shape of the conductor 42a, and the top surface shape of the second depressed portion of the oxide 30 is the same as the top surface shape of the conductor 42b.

An opening reaching the oxide 30 is provided in an insulator 80. The opening includes a region overlapping with the third depressed portion of the oxide 30. In other words, the third depressed portion overlaps with the opening provided in the insulator 80. The insulator 50 and the conductor 60 are provided in the opening and inside the third depressed portion. That is, the conductor 60 is provided over the insulator 50. The conductor 60 includes a region overlapping with the oxide 30 with the insulator 50 therebetween. The insulator 50 includes a region in contact with a side surface of the conductor 60 and a region in contact with the bottom surface of the conductor 60.

The conductor 60 functions as a gate electrode. The insulator 50 functions as a gate insulator. Note that the gate insulator is also referred to as a gate insulating layer or a gate insulating film in some cases. The conductor 42a functions as one of a source electrode and a drain electrode, and the conductor 42b functions as the other of the source electrode and the drain electrode. At least part of a region of the oxide 30 overlapping with the conductor 60 functions as a channel formation region.

In the transistor 10, a metal oxide functioning as a semiconductor (hereinafter, also referred to as an oxide semiconductor) is preferably used in the oxide 30 including the channel formation region.

The metal oxide functioning as a semiconductor preferably has a band gap of 2 eV or higher, further preferably 2.5 eV or higher. With the use of a metal oxide having a wide bandgap, the off-state current of the transistor can be reduced. Note that the off-state current refers to a current that flows between a source and a drain when the transistor is in an off state.

The oxide 30 preferably has crystallinity. It is particularly preferable to use a CAAC-OS (c-axis aligned crystalline oxide semiconductor) as the oxide 30.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

Although FIG. 1A to FIG. 1D illustrate a single-layer structure of the oxide 30, the present invention is not limited to this structure, and a stacked-layer structure of two or more layers may be employed.

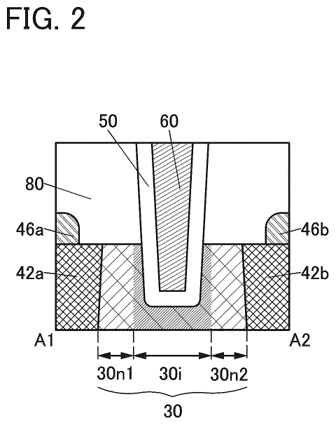

Here, FIG. 2 illustrates an enlarged view of the vicinity of the channel formation region in FIG. 1B. The oxide 30 includes a region 30n1, a region 30n2, and a region 30i. At least part of the region 30i overlaps with the conductor 60. The region 30i is positioned between the region 30n1 and the region 30n2. The region 30n1 is positioned between the conductor 42a and the region 30i, and the region 30n2 is positioned between the conductor 42b and the region 30i. In other words, the region 30i is positioned between the conductor 42a and the conductor 42b.

At least part of the region 30i functions as a channel formation region of the transistor 10. At least part of the region 30n1 functions as one of a source region and a drain region of the transistor 10, and at least part of the region 30n2 functions as the other of the source region and the drain region of the transistor 10.

The region 30i has a smaller amount of oxygen vacancies or a lower impurity concentration than the region 30n1 and the region 30n2, and thus is a high-resistance region with a low carrier concentration. Thus, the region 30i can be regarded as being i-type (intrinsic) or substantially i-type.

Here, the carrier concentration of the region 30i is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the region 30i is not particularly limited and can be, for example, 1×10⁻⁹ cm⁻³.

The region 30n1 and the region 30n2 include a large amount of oxygen vacancies or have a high concentration of an impurity such as hydrogen, nitrogen, or a metal element, and thus are each a low-resistance region with an increased carrier concentration. In other words, the region 30n1 and the region 30n2 are each an n-type region having a higher carrier concentration and a lower resistance than the region 30i.

Between the region 30i and the region 30n1 or the region 30n2, a region having a carrier concentration that is lower than or substantially equal to the carrier concentrations in the region 30n1 and the region 30n2 and higher than or substantially equal to the carrier concentration in the region 30i may be formed. That is, the region functions as a junction region between the region 30i and the region 30n1 or the region 30n2. The hydrogen concentration in the junction region is lower than or substantially equal to the hydrogen concentrations in the region 30n1 and the region 30n2 and higher than or substantially equal to the hydrogen concentration in the region 30i in some cases. The amount of oxygen vacancies in the junction region is smaller than or substantially equal to the amounts of oxygen vacancies in the region 30n1 and the region 30n2 and larger than or substantially equal to the amount of oxygen vacancies in the region 30i in some cases.

In the oxide 30, the boundaries between the regions are difficult to detect clearly in some cases. The concentration of a metal element and an impurity element such as hydrogen or nitrogen, which is detected in each region, may be not only gradually changed between the regions but also continuously changed in each region. That is, the region closer to the channel formation region preferably has a lower concentration of an impurity element such as hydrogen or nitrogen.

A region functioning as a source region or a drain region is preferably large.

Specifically, the area of a region where the conductor 42a or the conductor 42b is in contact with the oxide 30 is preferably large. When the region is increased, the contact resistance between the oxide semiconductor and the source electrode or the drain electrode is reduced, whereby the on-state characteristics of the transistor can be improved.

Note that in the structure in which the conductor 42a and the conductor 42b are provided above the oxide 30, in order to increase the area of the region where the conductor 42a or the conductor 42b is in contact with the oxide 30, the areas of the conductor 42a and the conductor 42b in the top view need to be increased. Thus, miniaturization or high integration of the semiconductor device including the transistor is difficult.

Thus, in this embodiment, the conductor 42a is provided to fill the first depressed portion formed in the oxide 30, and the conductor 42b is provided to fill the second depressed portion formed in the oxide 30. When the first depressed portion and the second depressed portion are deep, the area of the region where the conductor 42a or the conductor 42b is in contact with the oxide 30 can be increased without increasing the areas of the conductor 42a and the conductor 42b in the top view. Accordingly, the contact resistance between the oxide semiconductor and the source electrode or the drain electrode can be reduced, and the semiconductor device including the transistor can be miniaturized or highly integrated while the on-state characteristics of the transistor are improved.

Note that extraction of oxygen in the CAAC-OS is likely to occur in a side surface of the CAAC-OS compared to the top surface of the CAAC-OS. When the conductor 42a and the conductor 42b are provided in the first depressed portion and the second depressed portion which are provided in the oxide 30, respectively, the conductor 42a and the conductor 42b are in contact with a sidewall of the first depressed portion and a sidewall of the second depressed portion, respectively. That is, the conductor 42a and the conductor 42b are in contact with the side surface of the CAAC-OS. At this time, oxygen is likely to be extracted in the region 30n1 in contact with the conductor 42a and the region 30n2 in contact with the conductor 42b. Thus, the region 30n1 and the region 30n2 are regions having lower resistance than the region 30i and can be n-type regions.

Meanwhile, the region 30i is in contact with the insulator 50. When oxygen contained in the insulator 50 is supplied to the region 30i, oxygen vacancies in the region 30i are reduced. Thus, the region 30i becomes a region having higher resistance than the region 30n1 and the region 30n2, and can be an i-type (intrinsic) or substantially i-type.

With the above structure, the region 30i functioning as the channel formation region can be an i-type or substantially i-type region, the region 30n1 and the region 30n2 functioning as the source region and the drain region can be n-type regions, and thus a semiconductor device with favorable electrical characteristics can be provided.

Thus, a semiconductor device with favorable electrical characteristics can be provided. Alternatively, a semiconductor device that can be miniaturized or highly integrated can be provided. Alternatively, a semiconductor device that has favorable electrical characteristics and can be miniaturized or highly integrated can be provided.

In the semiconductor device illustrated in FIG. 1A to FIG. 1D, as illustrated in FIG. 1B, the bottom surface of the conductor 42a is positioned below the bottom surface of the insulator 50 in a region overlapping with the oxide 30, and the bottom surface of the conductor 42b is positioned below the bottom surface of the insulator 50 in the region overlapping with the oxide 30. In other words, the bottom surface of the first depressed portion of the oxide 30 is positioned closer to the bottom surface side of the oxide 30 than the bottom surface of the third depressed portion of the oxide 30, and the bottom surface of the second depressed portion of the oxide 30 is positioned closer to the bottom surface side of the oxide 30 than the bottom surface of the third depressed portion of the oxide 30.

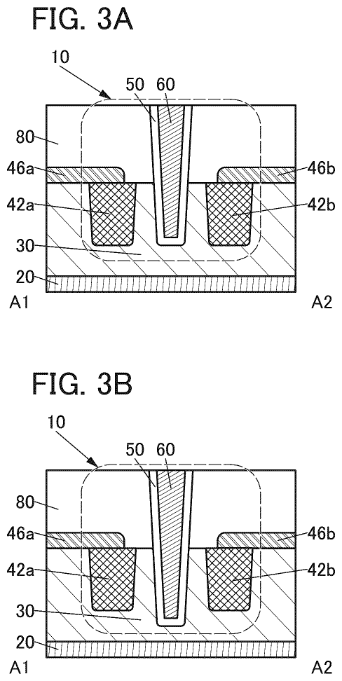

Note that the positional relation between the bottom surface of the conductor 42a and the bottom surface of the conductor 42b, and the bottom surface of the insulator 50 in a region overlapping with the oxide 30 is not limited to the above. For example, as illustrated in FIG. 3A, the bottom surface of the conductor 42a and the bottom surface of the conductor 42b may each be level with or substantially level with the bottom surface of the insulator 50 in the region overlapping with the oxide 30. In other words, the bottom surface of the first depressed portion and the bottom surface of the second depressed portion may each be level with or substantially level with the bottom surface of the third depressed portion. With such a structure, the processing conditions of the oxide 30 at the time of forming the first depressed portion and the second depressed portion can be similar to the processing conditions of the oxide 30 at the time of forming the third depressed portion; thus, variations in the depth of the depressed portion can be small. The channel length is suitably a distance between the source electrode and the drain electrode, in which case the channel length is easily controlled.

Alternatively, as illustrated in FIG. 3B, for example, the bottom surface of the conductor 42a may be positioned above the bottom surface of the insulator 50 in the region overlapping with the oxide 30, and the bottom surface of the conductor 42b may be positioned above the bottom surface of the insulator 50 in the region overlapping with the oxide 30. In other words, the bottom surface of the first depressed portion may be positioned closer to the top surface side of the oxide 30 than the bottom surface of the third depressed portion, and the bottom surface of the second depressed portion may be positioned closer to the top surface side of the oxide 30 than the bottom surface of the third depressed portion. With such a structure, an effective channel length can be long while the distance between a source and a drain is kept short. Therefore, a semiconductor device with a reduced short-channel effect and favorable electrical characteristics can be provided. Alternatively, a semiconductor device that can be miniaturized or highly integrated can be provided.

The short-channel effect refers to degradation of electrical characteristics which becomes obvious along with miniaturization of a transistor (a decrease in channel length). The short-channel effect results from the effect of an electric field of a drain on a source. Specific examples of the short-channel effect include a decrease in threshold voltage, an increase in subthreshold swing value (S value), an increase in leakage current, and the like. Here, S value means the amount of change in a gate voltage in the subthreshold region when the drain voltage keeps constant and the drain current changes by one digit.

Note that FIG. 3A and FIG. 3B are each a cross-sectional view of a portion indicated by the dashed-dotted line A1-A2 in FIG. 1A, and is also a cross-sectional view of the transistor 10 in the channel length direction.

As illustrated in FIG. 1A to FIG. 1D, the semiconductor device of one embodiment of the present invention includes an insulator 20 over a substrate (not illustrated), the transistor 10 over the insulator 20, the insulator 80 over the transistor 10, an insulator 35a, and an insulator 35b. The insulator 35a, the insulator 35b, and the insulator 80 function as interlayer films. A conductor 46a electrically connected to the conductor 42a is provided over the oxide 30, and a conductor 46b electrically connected to the conductor 42b is provided over the oxide 30.

The distance from the bottom surface of the third depressed portion of the oxide 30 to the top surface of the insulator 20 needs to be kept being higher than or equal to a certain distance. For example, when the third depressed portion reaches the top surface of the insulator 20, no channel formation region can be provided. In addition, in the oxide 30 in the vicinity of the insulator 20, the CAAC structure is difficult to be formed in some cases; thus, a channel formation region might have no CAAC structure when the distance is short. Thus, the distance is greater than or equal to 2 nm, preferably greater than or equal to 3 nm, further preferably greater than or equal to 5 nm. When the distance is increased, the effective channel width is increased, so that the on-state characteristics of the transistor 10 can be increased. However, when the distance is too long, the productivity of the semiconductor device is decreased. Thus, the distance is less than or equal to 500 nm, preferably less than or equal to 200 nm, further preferably less than or equal to 150 nm, still further preferably less than or equal to 100 nm.

As illustrated in FIG. 1B and FIG. 1D, the sidewall of the first depressed portion of the oxide 30 and the sidewall of the second depressed portion of the oxide 30 may each have a tapered shape. In this specification and the like, a tapered shape indicates a shape in which at least part of a side surface of a structure is inclined to a substrate surface. For example, the angle formed between the inclined side surface and the substrate surface (the angle is also referred to as a taper angle) is preferably less than 90°. The sidewalls may have a taper angle greater than or equal to 60° and less than 90°, for example. When the above sidewalls each have a tapered shape, the coverage of conductive films that are to be the conductor 42a and the conductor 42b can be improved in a later step, so that defects such as a void can be reduced.

However, without limitation to the above, the sidewalls may be substantially perpendicular to the bottom surface of the oxide 30. With such a structure, a plurality of transistors 10 can be provided with high density in a small area.

As illustrated in FIG. 1B, a sidewall of the third depressed portion of the oxide 30 and a sidewall of the opening of the insulator 80 may each have a tapered shape. The sidewalls may have a taper angle greater than or equal to 60° and less than 90°, for example. When the above sidewalls each have a tapered shape, the coverage of an insulating film to be the insulator 50 and a conductive film to be the conductor 60 can be improved in a later step, so that defects such as a void can be reduced.

However, without limitation to the above, the sidewalls may be substantially perpendicular to the bottom surface of the oxide 30. With such a structure, the plurality of transistors 10 can be provided with high density in a small area.

In FIG. 1A and FIG. 1C, in a cross-sectional view in the channel width direction of the transistor 10, a structure where the width of the oxide 30 in a region overlapping with the conductor 60 is the same as the width of the oxide 30 in a region not overlapping with the conductor 60 is illustrated; however, the present invention is not limited thereto.

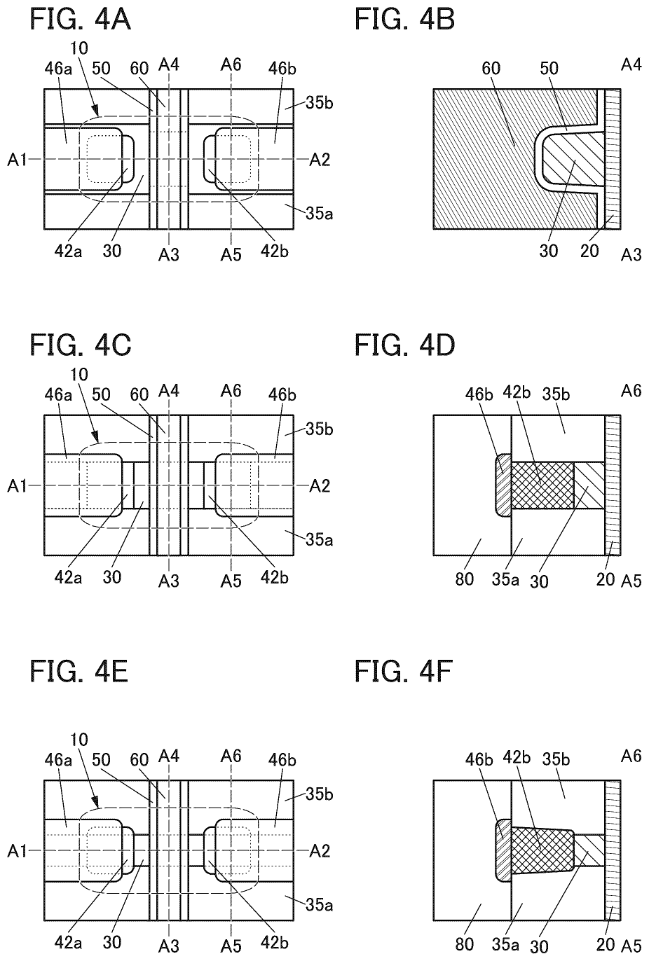

FIG. 4A and FIG. 4B illustrate a top view and a cross-sectional view, respectively, of the semiconductor device including a transistor where the shape of the oxide 30 is different from the transistor 10 illustrated in FIG. 1A to FIG. 1D. FIG. 4A is a top view of the semiconductor device. FIG. 4B is a cross-sectional view of the semiconductor device. FIG. 4B is a cross-sectional view of a portion indicated by the dashed-dotted line A3-A4 in FIG. 4A, and is also a cross-sectional view of the transistor 10 in the channel width direction. Note that the cross-sectional view of the semiconductor device of a portion indicated by the dashed-dotted line A1-A2 in FIG. 4A and the cross-sectional view of the semiconductor device of a portion indicated by the dashed-dotted line A5-A6 in FIG. 4A are the same as the cross-sectional view of the semiconductor device illustrated in FIG. 1B and the cross-sectional view of the semiconductor device illustrated in FIG. 1D, respectively. For clarity of the drawing, some components are not illustrated in the top view of FIG. 4A.

As illustrated in FIG. 4A and FIG. 4B, in the cross-sectional view of the transistor 10 in the channel width direction, the width of the oxide 30 in the region overlapping with the conductor 60 may be smaller than the width of the oxide 30 in the region not overlapping with the conductor 60. This is because part of the side surface of the oxide 30 in a region overlapping with the opening included in the insulator 80 is sometimes removed when the third depressed portion is formed in the oxide 30.

As illustrated in FIG. 1A and FIG. 1D, the semiconductor device illustrated in FIG. 1A to FIG. 1D has a structure in which the width of the oxide 30 in the channel width direction is larger than each of the widths of the conductor 42a and the conductor 42b in the channel width direction. Note that the present invention is not limited thereto.

FIG. 4C and FIG. 4D illustrate a top view and a cross-sectional view, respectively, of the semiconductor device including a transistor where the structures of the conductor 42a, the conductor 42b, and the oxide 30 are different from those in the transistor 10 illustrated in FIG. 1A to FIG. 1D. FIG. 4C is a top view of the semiconductor device. FIG. 4D is a cross-sectional view of the semiconductor device. FIG. 4D is a cross-sectional view of a portion indicated by the dashed-dotted line A5-A6 in FIG. 4C. Note that the cross-sectional view of the semiconductor device of a portion indicated by the dashed-dotted line A1-A2 in FIG. 4C and the cross-sectional view of the semiconductor device of a portion indicated by the dashed-dotted line A3-A4 in FIG. 4C are the same as the cross-sectional view of the semiconductor device illustrated in FIG. 1B and the cross-sectional view of the semiconductor device illustrated in FIG. 1C, respectively. Note that for clarity of the drawing, some components are not illustrated in the top view of FIG. 4C.

As illustrated in FIG. 4C and FIG. 4D, the width of the oxide 30 in the channel width direction may be the same or substantially the same as each of the widths of the conductor 42a and the conductor 42b in the channel width direction. With such a structure, the curve region of the top surface shape of each of the conductor 42a and the conductor 42b is reduced, so that the area of side surfaces where the conductor 42a and the conductor 42b face each other is increased. Thus, a region functioning as the source region or the drain region is increased, so that the on-state current of the transistor can be increased and the frequency characteristics of the transistor can be improved.

FIG. 4E and FIG. 4F illustrate a top view and a cross-sectional view, respectively, of the semiconductor device including a transistor where the structures of the conductor 42a, the conductor 42b, and the oxide 30 are different from those of the transistor 10 illustrated in FIG. 1A to FIG. 1D. FIG. 4E is a top view of the semiconductor device. FIG. 4F is a cross-sectional view of the semiconductor device. FIG. 4F is a cross-sectional view of a portion indicated by the dashed-dotted line A5-A6 in FIG. 4E. Note that the cross-sectional view of the semiconductor device of a portion indicated by the dashed-dotted line A1-A2 in FIG. 4E and the cross-sectional view of the semiconductor device of a portion indicated by the dashed-dotted line A3-A4 in FIG. 4E are the same as the cross-sectional view of the semiconductor device illustrated in FIG. 1B and the cross-sectional view of the semiconductor device illustrated in FIG. 1C, respectively. Note that for clarity of the drawing, some components are not illustrated in the top view of FIG. 4E.

As illustrated in FIG. 4E and FIG. 4F, the width of the oxide 30 in the channel width direction may be smaller than each of the widths of the conductor 42a and the conductor 42b in the channel width direction. In that case, the conductor 42a and the conductor 42b each include a region overlapping with the insulator 35a and a region overlapping with the insulator 35b.

For example, as the oxide 30, a metal oxide such as In-M-Zn oxide containing indium, an element M, and zinc (the element M is one or more kinds selected from aluminum, gallium, yttrium, tin, boron, silicon, vanadium, beryllium, copper, titanium, iron, nickel, germanium, zirconium, molybdenum, lanthanum, cerium, neodymium, hafnium, tantalum, tungsten, magnesium, cobalt, and the like) is preferably used. Alternatively, In-M oxide, In—Zn oxide, or indium oxide may be used as the oxide 30.

As the oxide 30, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, or a metal oxide with a composition of In:M:Zn=5:1:3 [atomic ratio] or in the neighborhood thereof may be specifically used. Note that a composition in the neighborhood includes the range of +30% of an intended atomic ratio. Gallium is preferably used as the element M.

A conductive material that is not easily oxidized, a conductive material having a function of inhibiting diffusion of oxygen, or the like is preferably used as the conductor 42a and the conductor 42b. Examples of the conductive material include a conductive material containing nitrogen, a conductive material containing oxygen, and the like. Accordingly, it is possible to inhibit a reduction in the conductivity of the conductor 42a and the conductor 42b. In the case where a conductive material containing a metal element and nitrogen is used for each of the conductor 42a and the conductor 42b, the conductor 42a and the conductor 42b contain at least a metal element and nitrogen.

As the conductor 42a and the conductor 42b, for example, a nitride containing tantalum, a nitride containing titanium, a nitride containing molybdenum, a nitride containing tungsten, a nitride containing tantalum and aluminum, or a nitride containing titanium and aluminum is preferably used. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

In one embodiment of the present invention, a nitride containing tantalum or a nitride containing titanium is particularly preferably used as the conductor 42a and the conductor 42b. In this case, the conductor 42a and the conductor 42b contain nitrogen and tantalum or titanium.

Note that hydrogen contained in the oxide 30 or the like diffuses into the conductor 42a or the conductor 42b in some cases. In particular, when a nitride containing tantalum is used as the conductor 42a and the conductor 42b, hydrogen contained in the oxide 30 or the like is likely to diffuse into the conductor 42a or the conductor 42b, and the diffused hydrogen is bonded to nitrogen contained in the conductor 42a or the conductor 42b in some cases. That is, hydrogen contained in the oxide 30 or the like is absorbed by the conductor 42a or the conductor 42b in some cases.

When heat treatment is performed in the state where the oxide 30 and the conductor 42a or the conductor 42b are in contact with each other, the sheet resistance of the oxide 30 in a region in contact with the conductor 42a or the conductor 42b is decreased in some cases. Furthermore, the carrier concentration sometimes increases. Thus, the resistance of the oxide 30 in a region overlapping with the conductor 42a or the conductor 42b can be lowered in a self-aligned manner. Although FIG. 1A to FIG. 1D illustrate a structure where each of the conductor 42a and the conductor 42b has a single-layer structure, the present invention is not limited to this structure, and a stacked-layer structure of two or more layers may be employed.

As the insulator 50, an insulator that easily transmits oxygen is preferably used. With such a structure, oxygen contained in the insulator 80 can be supplied to the region 30i through the insulator 50. As the insulator 50, for example, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable. In this case, the insulator 50 contains at least oxygen and silicon.

The concentration of impurities such as water and hydrogen in the insulator 50 is preferably reduced.

The thickness of the insulator 50 is preferably greater than or equal to 0.1 nm and less than or equal to 20 nm, further preferably greater than or equal to 0.5 nm and less than or equal to 15 nm. In particular, to manufacture a minute transistor, the thickness of the insulator 50 is preferably greater than or equal to 0.5 nm and less than or equal to 10 nm, further preferably greater than or equal to 0.5 nm and less than or equal to 5 nm. In that case, at least part of the insulator 50 preferably includes a region with the above-described thickness.

Although FIG. 1A to FIG. 1D illustrate a single-layer structure of the insulator 50, the present invention is not limited to this structure, and a stacked-layer structure of two or more layers may be employed.

As the conductor 60, a conductive material containing tungsten, copper, or aluminum as its main component is preferably used. The conductor 60 may have a stacked-layer structure, for example, a stack of any of the above conductive materials and titanium or titanium nitride may be employed.

As illustrated in FIG. 1C, when the top surface of the insulator 20 is regarded as a reference, a difference between the height of the bottom surface of the conductor 60 in a region not overlapping with the oxide 30 and the height of the bottom surface of the oxide 30 is equal to the thickness of the insulator 50. That is, by reducing the thickness of the insulator 50, the bottom surface of the conductor 60 in the region not overlapping with the oxide 30 is closer to the height of the bottom surface of the oxide 30 (the top surface of the insulator 20) in the channel width direction of the transistor 10. When the conductor 60 functioning as the gate electrode covers the side surface and the top surface of the channel formation region of the oxide 30 with the insulator 50 therebetween, the electric field of the conductor 60 can easily act on the entire channel formation region of the oxide 30. Hence, the transistor 10 can have a higher on-state current and improved frequency characteristics.

The insulator 20 preferably functions as a barrier insulating film that inhibits diffusion of impurities such as water and hydrogen into the transistor 10 from the substrate side. Accordingly, as the insulator 20, it is preferable to use an insulating material that has a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, it is preferable to use an insulating material having a function of inhibiting diffusion of oxygen (e.g., at least one of oxygen atoms, oxygen molecules, and the like) (an insulating material through which the oxygen is less likely to pass).

Note that in this specification, a barrier insulating film refers to an insulating film having a barrier property. A barrier property in this specification means a function of inhibiting diffusion of a targeted substance (also referred to as having low permeability). In addition, the barrier property in this specification means a function of capturing and fixing (also referred to as gettering) a targeted substance.

As the insulator 20, an insulator having a function of inhibiting diffusion of oxygen and impurities such as water and hydrogen is preferably used. As the insulator 20, aluminum oxide, magnesium oxide, hafnium oxide, gallium oxide, indium gallium zinc oxide, silicon nitride, silicon nitride oxide, or the like can be used, for example. As the insulator 20, an insulator having a higher hydrogen barrier property may be used. For example, it is preferable that silicon nitride or the like be used as the insulator 20. As the insulator 20, an insulator which has an excellent function of capturing and fixing hydrogen may be used. For example, aluminum oxide or magnesium oxide is preferably used as the insulator 20. In this case, impurities such as water and hydrogen can be inhibited from diffusing to the transistor 10 from the substrate side through the insulator 20. Alternatively, oxygen contained in the oxide 30 can be inhibited from diffusing to the substrate side through the insulator 20.

Here, an oxide having an amorphous structure is preferably used as the insulator 20. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 10 or provided around the transistor 10, hydrogen contained in the transistor 10 or hydrogen present around the transistor 10 can be captured or fixed. In particular, hydrogen contained in the channel formation region of the transistor 10 is preferably captured or fixed. The metal oxide having an amorphous structure is used as the component of the transistor 10 or provided around the transistor 10, whereby the transistor 10 and a semiconductor device which have favorable characteristics and high reliability can be manufactured.

The insulator 20 preferably has an amorphous structure, but may partly include a region with a polycrystalline structure. Alternatively, the insulator 20 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

Although FIG. 1A to FIG. 1D illustrate a single-layer structure of the insulator 20, the present invention is not limited to this structure, and a stacked-layer structure of two or more layers may be employed.

The oxide 30, the insulator 35a, and the insulator 35b are provided over the insulator 20. In the top view, the oxide 30 is provided between the insulator 35a and the insulator 35b. In other words, in the top view, the insulator 35a and the insulator 35b are provided so as to sandwich the oxide 30. The top surface of the oxide 30 is level with or substantially level with the top surface of the insulator 35a and the top surface of the insulator 35b.

The insulator 80 is provided over the oxide 30, the conductor 42a, the conductor 42b, the insulator 35a, and the insulator 35b.

As the insulator 80, an insulator containing oxygen that is released by heating (hereinafter, sometimes referred to as excess oxygen) is preferably used. As the insulator 80, for example, an oxide containing silicon such as silicon oxide, silicon oxynitride, silicon oxide to which fluorine is added, silicon oxide to which carbon is added, silicon oxide to which carbon and nitrogen are added, or porous silicon oxide is preferably used. In particular, silicon oxide and silicon oxynitride, which are thermally stable, are preferable. A material such as silicon oxide, silicon oxynitride, or porous silicon oxide is preferable because a region containing excess oxygen can be easily formed.

Since the insulator 35a, the insulator 35b, and the insulator 80 function as interlayer films, the dielectric constant is preferably low. When a material with a low dielectric constant is used for an interlayer film, parasitic capacitance generated between wirings can be reduced. The oxide containing silicon is preferable because the oxide is a material with a low dielectric constant.

The concentration of impurities such as water and hydrogen in the insulator 35a, the insulator 35b, and the insulator 80 is preferably reduced.

The conductor 46a and the conductor 46b function as wirings. For each of the conductor 46a and the conductor 46b, a conductive material containing tungsten, copper, or aluminum as its main component is preferably used. The conductor 46a and the conductor 46b may each have a stacked-layer structure, for example, may be stacked layers of the above conductive material and titanium or titanium nitride.

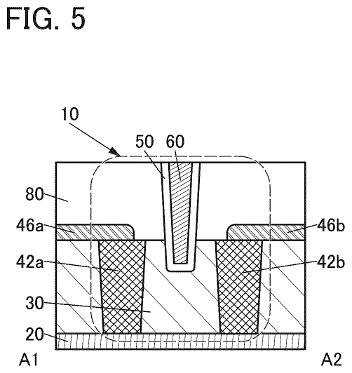

FIG. 1A and FIG. 1D illustrate a structure in which the bottom surface of the conductor 42a and the bottom surface of the conductor 42b are positioned above the bottom surface of the oxide 30. In other words, the bottom surface of the first depressed portion of the oxide 30 and the bottom surface of the second depressed portion of the oxide 30 are positioned above the bottom surface of the oxide 30. Note that the present invention is not limited thereto. For example, as illustrated in FIG. 5, the conductor 42a and the conductor 42b may be in contact with the top surface of the insulator 20. In other words, the first depressed portion and the second depressed portion may reach the insulator 20. When the insulator 20 functions as an etching stopper film at the time of forming the first depressed portion and the second depressed portion, the first depressed portion and the second depressed portion can be easily formed.

The semiconductor device illustrated in FIG. 1A to FIG. 1D has a structure where the insulator 80 is positioned between the conductor 46a and the insulator 50 and the insulator 80 is positioned between the conductor 46b and the insulator 50. Note that the present invention is not limited thereto.

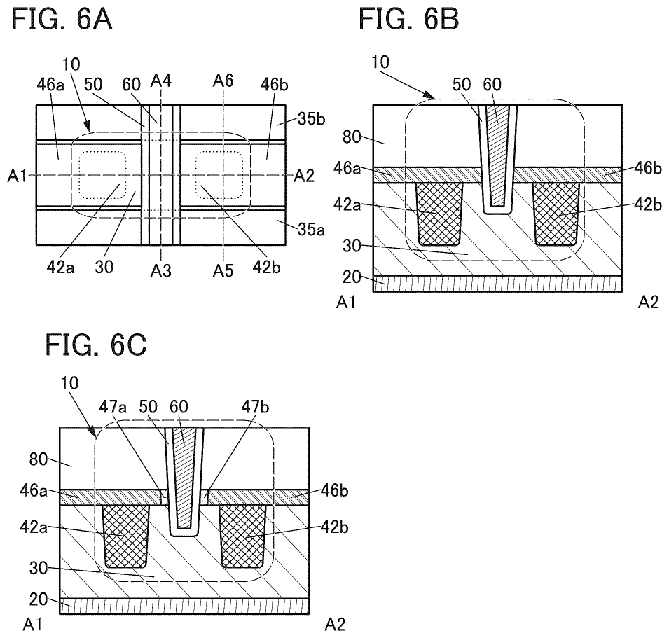

FIG. 6A and FIG. 6B illustrate a top view and a cross-sectional view, respectively, of a semiconductor device including a transistor where the structures of the conductor 46a and the conductor 46b are different from those in the transistor 10 illustrated in FIG. 1A to FIG. 1D. FIG. 6A is a top view of the semiconductor device. FIG. 6B is a cross-sectional view of the semiconductor device. FIG. 6B is a cross-sectional view of a portion indicated by the dashed-dotted line A1-A2 in FIG. 6A. Note that the cross-sectional view of the semiconductor device of a portion indicated by the dashed-dotted line A3-A4 in FIG. 6A and the cross-sectional view of the semiconductor device of a portion indicated by the dashed-dotted line A5-A6 in FIG. 6A are the same as the cross-sectional view of the semiconductor device illustrated in FIG. 1C and the cross-sectional view of the semiconductor device illustrated in FIG. 1D, respectively. For clarity of the drawing, some components are not illustrated in the top view of FIG. 6A.

As illustrated in FIG. 6A and FIG. 6B, the conductor 46a and the conductor 46b may be in contact with the insulator 50. At this time, the sidewall of the opening in the insulator 80 and a side surface of the conductor 46a are the same or substantially the same, and the sidewall of the opening in the insulator 80 and a side surface of the conductor 46b are the same or substantially the same. With such a structure, the conductor 60 can be placed properly in a region between the conductor 46a and the conductor 46b without positional alignment.

Note that as illustrated in FIG. 6C, when the conductor 46a and the insulator 50 are in contact with each other, the side surface of the conductor 46a is oxidized and an insulator 47a is formed in some cases. When the side surface of the conductor 46a is oxidized, the distance between the conductor 46a and the conductor 60 is increased, so that parasitic capacitance between the conductor 46a and the conductor 60 can be reduced. Similarly, when the conductor 46b and the insulator 50 are in contact with each other, the side surface of the conductor 46b is oxidized and an insulator 47b is formed in some cases. When the side surface of the conductor 46b is oxidized, parasitic capacitance between the conductor 46b and the conductor 60 can be reduced.

The semiconductor device illustrated in FIG. 1A to FIG. 1D illustrates a structure in which one transistor 10 is included. Note that the semiconductor device of this embodiment may include the plurality of transistors 10.

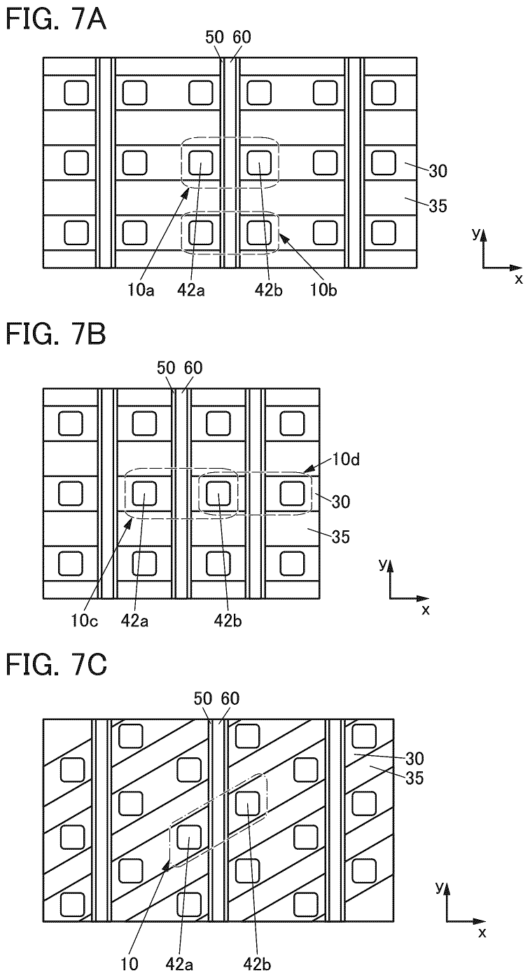

FIG. 7A illustrates a top view of a semiconductor device including a plurality of transistors. The x direction illustrated in FIG. 7A is parallel to the channel length direction of the transistor, and the y direction is perpendicular to the x direction. Note that for clarity of the drawing, some components are not illustrated in the top view of FIG. 7A.

The semiconductor device illustrated in FIG. 7A includes a plurality of transistors arranged in a matrix. In addition, a plurality of conductors 60 are provided to extend in the y direction. Note that each of the plurality of transistors has the same structure as the transistor 10 illustrated in FIG. 1A to FIG. 1D. A transistor 10a illustrated in FIG. 7A is one of the plurality of transistors. A transistor 10b illustrated in FIG. 7A is another transistor of the plurality of transistors and is adjacent to the transistor 10a in the y direction.

The semiconductor device illustrated in FIG. 7A includes an insulator 35 between the oxide 30 of the transistor 10a and the oxide 30 of the transistor 10b in a top view. In other words, the oxide 30 of the transistor 10a and the oxide 30 of the transistor 10b are isolated from each other. Note that the insulator 35 illustrated in FIG. 7A corresponds to the insulator 35a or the insulator 35b of the semiconductor device illustrated in FIG. 1A to FIG. 1D.

The semiconductor device illustrated in FIG. 7A includes the insulator 35 between adjacent transistors in the y direction. The semiconductor device illustrated in FIG. 7A has a structure where the oxides 30 are isolated from each other between the adjacent transistors in the y direction. Thus, generation of a parasitic transistor between the adjacent transistors in the y direction can be inhibited.

In the semiconductor device illustrated in FIG. 7A, the conductor 42a and the conductor 42b functioning as the source electrode and the drain electrode are each independently provided in the plurality of transistors. Note that one embodiment of the present invention is not limited thereto.

FIG. 7B illustrates a top view of a semiconductor device including a plurality of transistors. The x direction illustrated in FIG. 7B is parallel to the channel length direction of the transistor, and the y direction is perpendicular to the x direction. Note that for clarity of the drawing, some components are not illustrated in the top view of FIG. 7B.

The semiconductor device illustrated in FIG. 7B includes a plurality of transistors arranged in a matrix. In addition, the plurality of conductors 60 are provided to extend in the y direction. Note that each of the plurality of transistors has the same structure as the transistor 10 illustrated in FIG. 1A to FIG. 1D. A transistor 10c illustrated in FIG. 7B is one of the plurality of transistors. A transistor 10d illustrated in FIG. 7B is another transistor of the plurality of transistors and is adjacent to the transistor 10c in the x direction.

As illustrated in FIG. 7B, the conductor 42b of the transistor 10c also serves as one of a source electrode and a drain electrode of the transistor 10d. In other words, in the semiconductor device illustrated in FIG. 7B, the conductor 42b serves as both the other of the source electrode and the drain electrode of the transistor 10c and the one of the source electrode and the drain electrode of the transistor 10d. With the structure, a semiconductor device that can be miniaturized or highly integrated can be provided.

FIG. 7A illustrates a structure in which the oxide 30 extends in the x direction. Note that the present invention is not limited thereto. For example, as illustrated in FIG. 7C, the oxide 30 may extend in a direction different from the x direction and the y direction. At this time, the channel length direction of the transistor 10 is a direction different from the x direction and the y direction. With such a structure, the layout flexibility of the conductor 46a and the conductor 46b functioning as wirings (not illustrated in FIG. 7C) can be increased.

### Structure Example 2

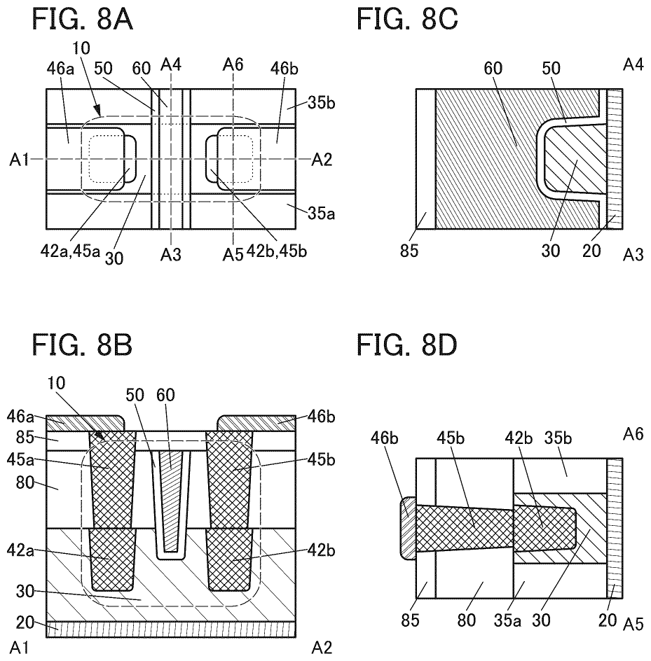

FIG. 8A to FIG. 8D illustrate structure examples different from those of the semiconductor device illustrated in FIG. 1A to FIG. 1D. FIG. 8A to FIG. 8D are a top view and cross-sectional views of a semiconductor device including the transistor 10. FIG. 8A is a top view of the semiconductor device. FIG. 8B to FIG. 8D are cross-sectional views of the semiconductor device. FIG. 8B is a cross-sectional view of a portion indicated by the dashed-dotted line A1-A2 in FIG. 8A, and is also a cross-sectional view of the transistor 10 in the channel length direction. FIG. 8C is a cross-sectional view of a portion indicated by the dashed-dotted line A3-A4 in FIG. 8A, and is also a cross-sectional view in the channel width direction of the transistor 10. FIG. 8D is a cross-sectional view of a portion indicated by the dashed-dotted line A5-A6 in FIG. 8A. Note that for clarity of the drawing, some components are not illustrated in the top view of FIG. 8A.

The semiconductor device illustrated in FIG. 8A to FIG. 8D is different from the semiconductor device illustrated in FIG. 1A to FIG. 1D mainly in including an insulator 85, a conductor 45a, and a conductor 45b. Differences from Structure Example 1 described above are mainly described below, and common portions are not described.

The semiconductor device illustrated in FIG. 8A to FIG. 8D includes the insulator 85 over the insulator 80, the conductor 45a embedded in openings provided in the insulator 85 and the insulator 80, and the conductor 45b embedded in openings provided in the insulator 85 and the insulator 80.

The conductor 45a includes a region in contact with the top surface of the conductor 42a, and the conductor 45b includes a region in contact with the top surface of the conductor 42b. The top surface of the conductor 45a and the top surface of the conductor 45b are each level with or substantially level with the top surface of the insulator 85. The conductor 45a and the conductor 45b function as plugs.

The conductor 46a includes a region in contact with the top surface of the conductor 45a, and the conductor 46b includes a region in contact with the top surface of the conductor 45b. The conductor 46a is electrically connected to the conductor 42a through the conductor 45a, and the conductor 46b is electrically connected to the conductor 42b through the conductor 45b.

Each of the conductor 45a and the conductor 45b is preferably provided using any of the above-described materials that can be used for the conductor 60.

The insulator 85 functions as an interlayer film. The insulator 85 is preferably provided using any of the above-described materials that can be used for the insulator 80.

With such a structure, the layout flexibility of the wiring can be increased.

### Structure Example 3

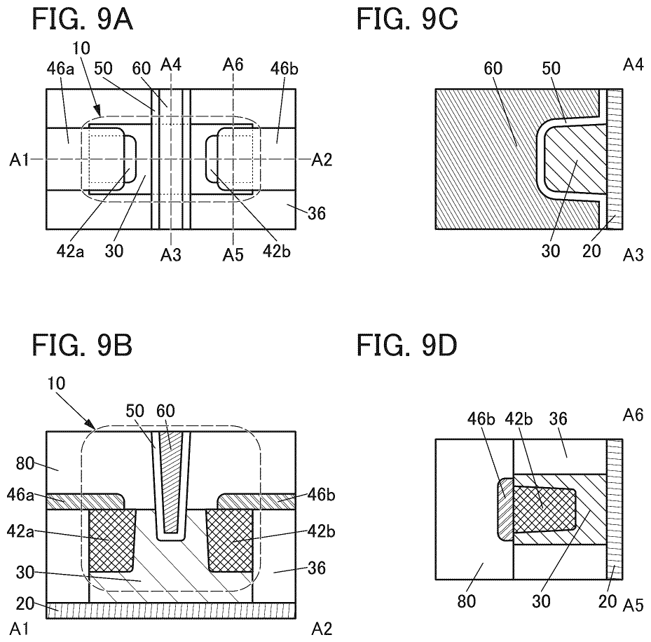

FIG. 9A to FIG. 9D illustrate structure examples different from those of the semiconductor device illustrated in FIG. 1A to FIG. 1D. FIG. 9A to FIG. 9D are a top view and cross-sectional views of a semiconductor device including the transistor 10. FIG. 9A is a top view of the semiconductor device. FIG. 9B to FIG. 9D are cross-sectional views of the semiconductor device. Here, FIG. 9B is a cross-sectional view of a portion indicated by the dashed-dotted line A1-A2 in FIG. 9A, and is also a cross-sectional view of the transistor 10 in the channel length direction. FIG. 9C is a cross-sectional view of a portion indicated by the dashed-dotted line A3-A4 in FIG. 9A, and is also a cross-sectional view of the transistor 10 in the channel width direction. FIG. 9D is a cross-sectional view of a portion indicated by the dashed-dotted line A5-A6 in FIG. 9A. Note that for clarity of the drawing, some components are not illustrated in the top view of FIG. 9A.

The semiconductor device illustrated in FIG. 9A to FIG. 9D is different from the semiconductor device illustrated in FIG. 1A to FIG. 1D mainly in that the insulator 35a and the insulator 35b are not included and an insulator 36 is included. Differences from Structure Example 1 described above are mainly described below, and common portions are not described.

The semiconductor device illustrated in FIG. 9A to FIG. 9D includes the insulator 36 over the insulator 20.

The insulator 36 is provided to surround four sides of the oxide 30 in the top view. In other words, the oxide 30 is surrounded by the insulator 36 in the top view. That is, the oxide 30 is formed in an island shape. The top surface of the insulator 36 is level with or substantially level with the top surface of the oxide 30. The insulator 80 is provided over the oxide 30, the conductor 42a, the conductor 42b, and the insulator 36.

With such a structure, the oxides 30 are isolated for each transistor 10. Thus, generation of a parasitic transistor between the transistor 10 and another transistor 10 adjacent to the transistor 10 can be inhibited.

### Structure Example 4

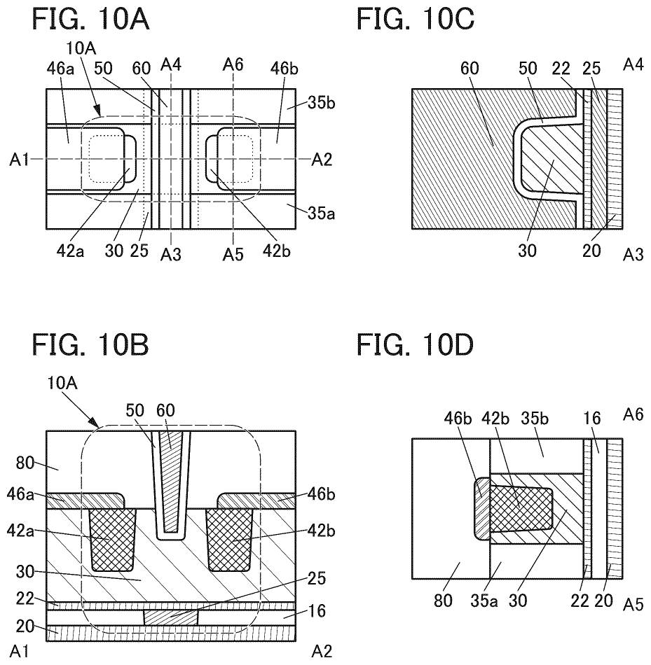

FIG. 10A to FIG. 10D illustrate a structure example different from that of the transistor 10. FIG. 10A to FIG. 10D are a top view and cross-sectional views of a semiconductor device including a transistor 10A. FIG. 10A is a top view of the semiconductor device. FIG. 10B to FIG. 10D are cross-sectional views of the semiconductor device. Here, FIG. 10B is a cross-sectional view of a portion indicated by the dashed-dotted line A1-A2 in FIG. 10A, and is also a cross-sectional view of the transistor 10A in the channel length direction. FIG. 10C is a cross-sectional view of a portion indicated by the dashed-dotted line A3-A4 in FIG. 10A, and is also a cross-sectional view of the transistor 10A in the channel width direction. FIG. 10D is a cross-sectional view of a portion indicated by the dashed-dotted line A5-A6 in FIG. 10A. Note that for clarity of the drawing, some components are not illustrated in the top view of FIG. 10A.

The semiconductor device including the transistor 10A is different from the semiconductor device including the transistor 10 mainly in including a conductor 25, an insulator 16, and an insulator 22. Differences from Structure Example 1 described above are mainly described below, and common portions are not described.

The transistor 10A includes the insulator 16 over the insulator 20, the conductor 25 provided to be embedded in the insulator 16, and the insulator 22 over the insulator 16 and the conductor 25. The oxide 30 is provided over the insulator 22.

The conductor 25 is provided to overlap with the oxide 30 and the conductor 60.

In the transistor 10A, the conductor 60 functions as a first gate (also referred to as a top gate) electrode, and the conductor 25 functions as a second gate (also referred to as a back gate) electrode. The insulator 50 functions as a first gate insulator, and the insulator 22 functions as a second gate insulator. The insulator 16 functions as an interlayer film.

As the conductor 25, a conductive material containing tungsten, copper, or aluminum as its main component is preferably used. The conductor 25 may have a stacked-layer structure; for example, stacked layers of titanium or titanium nitride and the above-described conductive material may be employed.

The conductor 25 sometimes functions as a second gate electrode. In that case, by changing a potential applied to the conductor 25 not in conjunction with but independently of a potential applied to the conductor 60, the threshold voltage (Vth) of the transistor 10A can be controlled. In particular, by applying a negative potential to the conductor 25, Vth of the transistor 10A can be further increased, and the off-state current can be reduced. Thus, a drain current at the time when a potential applied to the conductor 60 is 0 V can be lower in the case where a negative potential is applied to the conductor 25 than in the case where the negative potential is not applied to the conductor 25.

The electric resistivity of the conductor 25 is designed in consideration of the potential applied to the conductor 25, and the thickness of the conductor 25 is determined in accordance with the electric resistivity. The thickness of the insulator 16 is substantially equal to that of the conductor 25. The conductor 25 and the insulator 16 are preferably as thin as possible in the allowable range of the design of the conductor 25. When the thickness of the insulator 16 is reduced, the absolute amount of impurities such as hydrogen contained in the insulator 16 can be reduced, inhibiting the diffusion of the impurity into the oxide 30.

Note that as illustrated in FIG. 10A, the conductor 25 is preferably provided to be larger than a region of the oxide 30 that overlaps with the conductor 60. As illustrated in FIG. 10C, it is particularly preferable that the conductor 25 extend to a region outside an end portion of the oxide 30 in the channel width direction. That is, the conductor 25 and the conductor 60 preferably overlap with each other with the insulators therebetween on the outer side of the side surface of the oxide 30 in the channel width direction. With this structure, the channel formation region of the oxide 30 can be electrically surrounded by the electric field of the conductor 60 functioning as the first gate electrode and the electric field of the conductor 25 functioning as the second gate electrode. In this specification, a transistor structure where the channel formation region is electrically surrounded by the electric fields of the first gate electrode and the second gate electrode is referred to as a surrounded channel (S-channel) structure.

In this specification and the like, a transistor having the S-channel structure refers to a transistor having a structure in which a channel formation region is electrically surrounded by an electric field of one or the other of a pair of gate electrodes. The S-channel structure disclosed in this specification and the like has a structure different from a FIN-type structure and a planar structure. The S-channel structure disclosed in this specification and the like can also be regarded as a kind of the FIN-type structure. In this specification and the like, the FIN-type structure refers to a structure where two or more surfaces (specifically, two surfaces, three surfaces, four surfaces, or the like) of a channel are provided to be covered with a gate electrode. With the FIN-type structure and the S-channel structure, resistance to a short-channel effect can be enhanced, that is, a transistor in which a short-channel effect is less likely to occur can be provided.

When the transistor 10A has the above-described S-channel structure, the channel formation region can be electrically surrounded. Accordingly, the density of current flowing in the transistor can be improved, and it can be expected to improve the on-state current of the transistor or increase the field-effect mobility of the transistor.

Note that although FIG. 10A illustrates a transistor with the S-channel structure as the transistor 10A, the semiconductor device of one embodiment of the present invention is not limited thereto. For example, a transistor structure that can be employed in one embodiment of the present invention is one or more selected from a planar structure, a FIN-type structure, and a GAA structure.

Furthermore, as illustrated in FIG. 10C, the conductor 25 is extended to function as a wiring as well. However, without limitation to this structure, a structure in which a conductor functioning as a wiring is provided below the conductor 25 may be employed. In addition, the conductor 25 is not necessarily provided in each transistor. For example, the conductor 25 may be shared by a plurality of transistors.

It is preferable that the insulator 22 have a function of inhibiting diffusion of hydrogen (e.g., at least one of a hydrogen atom, a hydrogen molecule, and the like). In addition, it is preferable that the insulator 22 have a function of inhibiting diffusion of oxygen (e.g., at least one of an oxygen atom, an oxygen molecule, and the like).

As the insulator 22, an insulator containing an oxide of one or both of aluminum and hafnium, which is an insulating material, is preferably used. As the insulator, aluminum oxide, hafnium oxide, an oxide containing aluminum and hafnium (hafnium aluminate), or the like is preferably used. Alternatively, an oxide containing hafnium and zirconium, e.g., a hafnium-zirconium oxide is preferably used. In the case where the insulator 22 is formed using such a material, the insulator 22 functions as a layer that inhibits release of oxygen from the oxide 30 to the substrate side and diffusion of impurities such as hydrogen from the periphery of the transistor 10A into the oxide 30. Thus, providing the insulator 22 can inhibit diffusion of impurities such as hydrogen into the oxide 30 and inhibit generation of oxygen vacancies in the oxide 30. Moreover, the conductor 25 can be inhibited from reacting with oxygen contained in the oxide 30.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over these insulators may be used for the insulator 22.

For example, a single layer or stacked layers of an insulator(s) containing what is called a high-k material such as aluminum oxide, hafnium oxide, tantalum oxide, zirconium oxide, or hafnium-zirconium oxide may be used for the insulator 22. As miniaturization and high integration of transistors progress, a problem such as a leakage current may arise because of a thinner gate insulator. When a high-k material is used for an insulator functioning as the gate insulator, a gate potential at the time when the transistor operates can be reduced while the physical thickness is maintained. Furthermore, a substance with a high dielectric constant such as lead zirconate titanate (PZT), strontium titanate (SrTiO₃), or (Ba,Sr)TiO3 (BST) may be used as the insulator 22.

Note that the insulator 22 may have a stacked-layer structure of two or more layers. In that case, without limitation to a stacked-layer structure formed of the same material, a stacked-layer structure formed of different materials may be employed.

The dielectric constant of the insulator 16 is preferably lower than that of the insulator 22. When a material with a low dielectric constant is used for an interlayer film, parasitic capacitance generated between wirings can be reduced. As the insulator 16, for example, silicon oxide, silicon oxynitride, silicon oxide to which fluorine is added, silicon oxide to which carbon is added, silicon oxide to which carbon and nitrogen are added, or porous silicon oxide is appropriately used.

### Structure Example 5

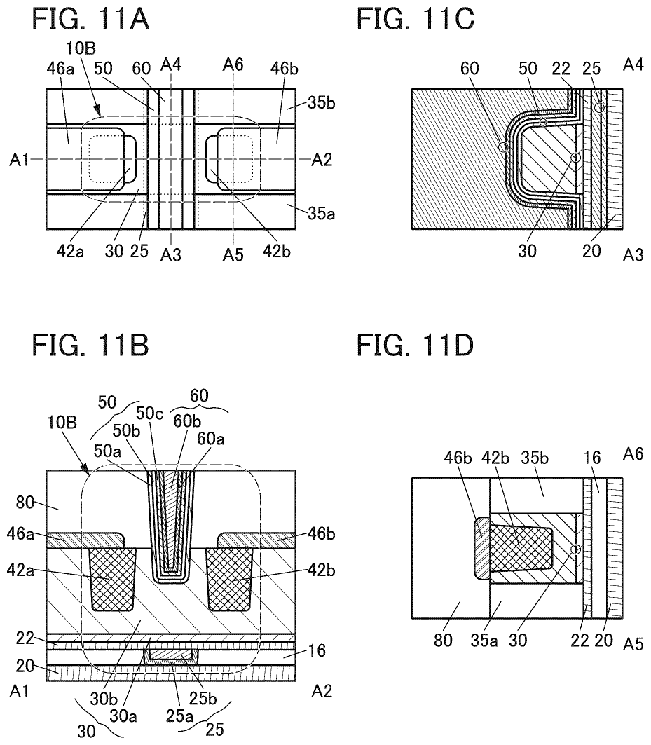

FIG. 11A to FIG. 11D illustrate a structure example different from that of the transistor 10A. FIG. 11A to FIG. 11D are a top view and cross-sectional views of the semiconductor device including a transistor 10B. FIG. 11A is a top view of the semiconductor device. FIG. 11B to FIG. 11D are cross-sectional views of the semiconductor device. Here, FIG. 11B is a cross-sectional view of a portion indicated by the dashed-dotted line A1-A2 in FIG. 11A, and is also a cross-sectional view of the transistor 10B in the channel length direction. FIG. 11C is a cross-sectional view of a portion indicated by the dashed-dotted line A3-A4 in FIG. 11A, and is also a cross-sectional view of the transistor 10B in the channel width direction. FIG. 11D is a cross-sectional view of a portion indicated by the dashed-dotted line A5-A6 in FIG. 11A. Note that for clarity of the drawing, some components are not illustrated in the top view in FIG. 11A.

The transistor 10B is different from the transistor 10A mainly in that the conductor 25, the oxide 30, the insulator 50, and the conductor 60 each have a stacked-layer structure. Differences from Structure Example 4 described above are mainly described below, and common portions are not described.

The conductor 25 includes a conductor 25a and a conductor 25b provided over the conductor 25a. The conductor 25a is provided in contact with the bottom surface and the side wall of the opening provided in the insulator 16. The conductor 25b is provided to be embedded in a depressed portion formed in the conductor 25a. Here, the top surface of the conductor 25b is level or substantially level with the top surface of the conductor 25a and the top surface of the insulator 16.

Here, as the conductor 25a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 25a is formed using a conductive material having a function of inhibiting diffusion of hydrogen, impurities such as hydrogen contained in the conductor 25b can be prevented from diffusing into the oxide 30 through the insulator 16, the insulator 22, and the like. When the conductor 25a is formed using a conductive material having a function of inhibiting diffusion of oxygen, the conductivity of the conductor 25b can be inhibited from being lowered because of oxidation. As the conductive material having a function of inhibiting diffusion of oxygen, for example, titanium, titanium nitride, tantalum, tantalum nitride, ruthenium, ruthenium oxide, or the like can be given. Thus, the conductor 25a may be a single layer or a stacked layer using the above conductive materials. For example, titanium nitride is used as the conductor 25a.

Moreover, the conductor 25b is preferably formed using a conductive material containing tungsten, copper, or aluminum as its main component. For example, tungsten is used as the conductor 25b.

The oxide 30 includes an oxide 30a provided over the insulator 22 and an oxide 30b provided over the oxide 30a.

The oxide 30 preferably has a stacked-layer structure of a plurality of oxide layers with different chemical compositions. For example, the atomic ratio of the element M to a metal element that is a main component of the metal oxide used as the oxide 30a is preferably greater than the atomic ratio of the element M to a metal element that is a main component of the metal oxide used as the oxide 30b. Moreover, the atomic ratio of the element M to In in the metal oxide used as the oxide 30a is preferably greater than the atomic ratio of the element M to In in the metal oxide used as the oxide 30b. With this structure, impurities and oxygen can be inhibited from diffusing into the oxide 30b from the components formed below the oxide 30a.

Furthermore, the atomic ratio of In to the element M in the metal oxide used as the oxide 30b is preferably greater than the atomic ratio of In to the element M in the metal oxide used as the oxide 30a. With this structure, the transistor 10B can have a high on-state current and high frequency characteristics.

When the oxide 30a and the oxide 30b contain a common element as the main component besides oxygen, the density of defect states at an interface between the oxide 30a and the oxide 30b can be made low. The density of defect states at the interface between the oxide 30a and the oxide 30b can be made low. Thus, the influence of interface scattering on carrier conduction is small, and the transistor 10B can have a high on-state current and excellent frequency characteristics.

Specifically, as the oxide 30a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof can be used. A metal oxide that can be used as the oxide 30 can be used as the oxide 30b. Gallium is preferably used as the element M.

The insulator 50 includes an insulator 50a, an insulator 50b provided over the insulator 50a, and an insulator 50c provided over the insulator 50b.

The insulator 50a preferably has a barrier property against oxygen. The thickness of the insulator 50a is preferably small. For example, the thickness of the insulator 50a preferably includes a region having a smaller thickness than the thickness of the insulator 50b. The insulator 50a is provided between the insulator 50b and the oxide 30. When the thickness of the insulator 50a is reduced, oxygen contained in the insulator 50b can be supplied to the region 30i of the oxide 30 and oxygen contained in the insulator 50b can be inhibited from being excessively supplied. Furthermore, when heat treatment or the like is performed, release of oxygen from the region 30i of the oxide 30 can be inhibited. Thus, the transistor 10 can have favorable electrical characteristics and higher reliability.

An insulator containing an oxide of one or both of aluminum and hafnium may be used as the insulator 50a. As the insulator, aluminum oxide, hafnium oxide, an oxide containing aluminum and hafnium (hafnium aluminate), an oxide containing hafnium and silicon (hafnium silicate), or the like can be used. As the insulator 50a, aluminum oxide can be used, for instance. In this case, the insulator 50a contains at least oxygen and aluminum.

The thickness of the insulator 50a is greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, it is acceptable that at least part of the insulator 50a has a region with a thickness like the above-described thickness. The thickness of the insulator 50a is preferably smaller than the thickness of the insulator 50b. In this case, at least part of the insulator 50a may include a region having a thickness that is smaller than that of the insulator 50b.

To form the insulator 50a having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Therefore, the insulator 50a can be deposited on the side surface of the opening formed in the insulator 80 and the like, with a small thickness like the above-described thickness and a favorable coverage.

Note that some of precursors usable in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

As the insulator 50b, an insulator that easily transmits oxygen is preferably used. As the insulator 50b, an insulator that can be used as the insulator 50 described above may be used.

As the insulator 50c, a barrier insulating film against hydrogen is preferably used. The insulator 50c is provided between the insulator 50b and the conductor 60. Thus, diffusion of impurities such as hydrogen contained in the conductor 60 into the oxide 30 can be prevented. For example, silicon nitride deposited by a PEALD method may be used as the insulator 50c. In this case, the insulator 50c contains at least nitrogen and silicon.

The insulator 50c preferably has a barrier property against oxygen. With such a structure, oxygen contained in the insulator 50b can be prevented from diffusing into the conductor 60 to inhibit the oxidation of the conductor 60. Note that the insulator 50c is less permeable to oxygen than at least the insulator 50b is.

Furthermore, the insulator 50c needs to be provided in an opening formed in the insulator 80 and the like, together with the insulator 50a, the insulator 50b, and the conductor 60. The thickness of the insulator 50c is preferably thin for miniaturization of the transistor 10B. The thickness of the insulator 50c is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, it is acceptable that at least part of the insulator 50c has a region with a thickness like the above-described thickness. The thickness of the insulator 50c is preferably smaller than the thickness of the insulator 50b. In this case, at least part of the insulator 50c may include a region having a thickness that is smaller than that of the insulator 50b.

An insulator may be provided between the insulator 50b and the insulator 50c. As the insulator, an insulating material that is a high-k material with a high relative dielectric constant may be used. With such a structure, a stacked-layer structure that is thermally stable and has a high relative dielectric constant can be obtained. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the breakdown voltage of the insulator 50 can be increased.

The conductor 60 includes a conductor 60a and a conductor 60b provided over the conductor 60a. For example, the conductor 60a is preferably provided to cover the bottom surface and the side surfaces of the conductor 60b.

As the conductor 60a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the conductor 60a has a function of inhibiting diffusion of oxygen, the conductivity of the conductor 60b can be inhibited from being lowered because of oxidation due to oxygen contained in the insulator 50. As the conductive material having a function of inhibiting diffusion of oxygen, for example, titanium, titanium nitride, tantalum, tantalum nitride, ruthenium, or ruthenium oxide is preferably used.

The conductor 60 also functions as a wiring and thus is preferably formed using a conductor having high conductivity. For example, a conductive material containing tungsten, copper, or aluminum as its main component can be used as the conductor 60b. The conductor 60b may have a stacked-layer structure; for example, a stacked-layer structure of the conductive material and titanium or titanium nitride may be employed.

### <Component Materials of Semiconductor Device>

Component materials that can be used for the semiconductor device are described below.

### <<Substrate>>

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used as the insulator functioning as a gate insulator, the voltage during operation of the transistor can be lowered while the physical thickness of the gate insulator is maintained. In contrast, when a material with a low relative dielectric constant is used as the insulator functioning as an interlayer film, parasitic capacitance generated between wirings can be reduced. Thus, a material is preferably selected depending on the function of an insulator.

Examples of the insulator with a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 30, oxygen vacancies included in the oxide 30 can be reduced.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. Alternatively, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

As the conductor functioning as the gate electrode, it is preferable to use, in particular, a conductive material containing oxygen and a metal element contained in the metal oxide where the channel is formed. Alternatively, a conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxide 30 is preferably formed using a metal oxide functioning as a semiconductor (an oxide semiconductor). A metal oxide that can be used as the oxide 30 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, an element M, and zinc is considered. The element M is aluminum, gallium, yttrium, or tin. Examples of other elements that can be used as the element M include boron, silicon, vanadium, beryllium, copper, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also referred to as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, an XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the presence of crystals in the film or the substrate. In other words, the crystal structure of the film or the substrate cannot be regarded as amorphous unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass is in an amorphous state. Furthermore, not a halo pattern but a spot-like pattern is observed in the diffraction pattern of the In—Ga—Zn oxide film deposited at room temperature. Thus, it is suggested that the In—Ga—Zn oxide deposited at room temperature is in an intermediate state, which is neither a single crystal nor polycrystal nor an amorphous state, and it cannot be concluded that In—Ga—Zn oxide is in an amorphous state.

### <<Structure of Oxide Semiconductor>>

Oxide semiconductors may be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm). [a-like OS]

The a-like OS is an oxide semiconductor having a structure between those of the nc-OS and the amorphous oxide semiconductor. The a-like OS includes a void or a low-density region. That is, the a-like OS has low crystallinity as compared with the nc-OS and the CAAC-OS. Moreover, the a-like OS has higher hydrogen concentration in the film than the nc-OS and the CAAC-OS.

### <<Structure of Oxide Semiconductor>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] than the second region and has lower [Ga] than the second region. Moreover, the second region has higher [Ga] than the first region and has lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated, for example. Furthermore, in the case where the CAC-OS is formed by a sputtering method, any one or more selected from an inert gas (typically, argon), an oxygen gas, and a nitrogen gas is used as a deposition gas. The ratio of the flow rate of an oxygen gas in the total flow rate of the deposition gas during deposition is preferably as low as possible. For example, the ratio of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and it is confirmed from the EDX mapping that the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, the off-state current can be inhibited.

Thus, in the case where a CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when a CAC-OS is used for a transistor, a high on-state current (Iₒₙ), a high field-effect mobility (μ), and favorable switching operation can be achieved.

A transistor using the CAC-OS has high reliability. Thus, the CAC-OS is suitably used in a variety of semiconductor devices typified by a display device.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for the transistor. For example, the carrier concentration in the oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor with a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

If impurities and oxygen vacancies exist in a channel formation region of an oxide semiconductor, a transistor using the oxide semiconductor may have variable electrical characteristics and poor reliability. In some cases, hydrogen in the vicinity of an oxygen vacancy forms a defect that is the oxygen vacancy into which hydrogen enters (hereinafter sometimes referred to as VₒH), which generates an electron serving as a carrier. Therefore, when the channel formation region of the oxide semiconductor includes oxygen vacancies, the transistor tends to have normally-on characteristics (even when no voltage is applied to the gate electrode, the channel exists and current flows through the transistor). Thus, impurities, oxygen vacancies, and VₒH are preferably reduced as much as possible in the channel formation region of the oxide semiconductor. In other words, it is preferable that the region of the oxide semiconductor where a channel is formed have a reduced carrier concentration and be of an i-type (intrinsic) or substantially i-type.

As a countermeasure to the above, an insulator containing excess oxygen is provided in the vicinity of the oxide semiconductor and heat treatment is performed, so that oxygen can be supplied from the insulator to the oxide semiconductor to reduce oxygen vacancies and VoH. Note that too much oxygen supplied to the source region or the drain region might decrease the on-state current or the field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that electrical characteristics and reliability of the transistor might be adversely affected.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

A change in electrical characteristics of a transistor having an oxide semiconductor (an OS transistor) due to exposure to radiation is small, i.e., an OS transistor has high tolerance to radiation; thus, an OS transistor can be suitably used even in an environment where radiation might enter. For example, OS transistors can be suitably used in outer space. Specifically, OS transistors can be used as transistors in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in the semiconductor devices provided in remote control robots that are controlled remotely in demolishment of a reactor facility, taking out of a nuclear fuel or a fuel debris, a field investigation on a space with a large amount of radioactive substance, and the like.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the oxide semiconductor is set to 2×10¹⁸ atoms/cm³ or lower, preferably 2×10¹⁷ atoms/cm³ or lower.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

The use of an oxide semiconductor with sufficiently reduced impurities for the channel formation region of the transistor can provide stable electrical characteristics.

### <<Other Semiconductor Materials>

The oxide 30 can be rephrased as a semiconductor layer including a channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor such as silicon, a compound semiconductor such as gallium arsenide, or a layered material functioning as a semiconductor (also referred to as an atomic layer material or a two-dimensional material) is preferably used as a semiconductor material. In particular, a layered material functioning as a semiconductor is suitably used as a semiconductor material.

Here, in this specification and the like, the layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For the semiconductor layer, a transition metal chalcogenide functioning as a semiconductor is preferably used, for example. Specific examples of the transition metal chalcogenide which can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### Manufacturing Method Example 1

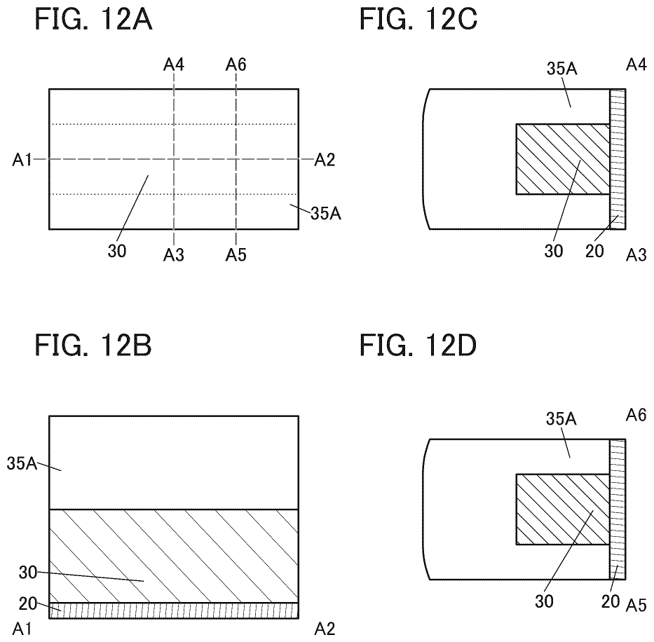

Next, an example of a method for manufacturing the semiconductor device of one embodiment of the present invention illustrated in FIG. 1A to FIG. 1D is described with reference to FIG. 12A to FIG. 18D.

Note that A of each drawing is a top view. Moreover, B of each drawing is a cross-sectional view corresponding to a portion indicated by the dashed-dotted line A1-A2 in A of each drawing, and is also a cross-sectional view of the transistor 10 in the channel length direction. Furthermore, C of each drawing is a cross-sectional view corresponding to a portion indicated by the dashed-dotted line A3-A4 in A of each drawing, and is also a cross-sectional view of the transistor 10 in the channel width direction. Furthermore, D of each drawing is a cross-sectional view of a portion indicated by the dashed-dotted line A5-A6 in A of each drawing. Note that for clarity of the drawing, some components are not illustrated in the top view of A of each drawing.

Hereinafter, an insulating material for forming an insulator, a conductive material for forming a conductor, or a semiconductor material for forming a semiconductor can be deposited by a sputtering method, a chemical vapor deposition (CVD) method, a molecular beam epitaxy (MBE) method, a pulsed laser deposition (PLD) method, an ALD method, or the like as appropriate.

Examples of the sputtering method include an RF sputtering method in which a high-frequency power source is used as a sputtering power source, a DC sputtering method in which a

DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. In contrast, such plasma damage is not caused in the case of a thermal CVD method not using plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are deposition methods that enable favorable step coverage almost regardless of the shape of an object to be processed. In particular, an ALD method has excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

By a CVD method, a film with a certain composition can be deposited depending on the flow rate ratio of the source gases. For example, by a CVD method, by changing the flow rate ratio of the source gases during the deposition, a film in which the composition is continuously changed can be deposited. In the case where the film is deposited while the flow rate ratio of the source gases is changed, as compared to the case where the film is deposited using a plurality of deposition chambers, the time taken for the deposition can be shortened because the time taken for transfer or pressure adjustment is omitted. Thus, the productivity of the semiconductor device can be increased in some cases.

In an ALD method, a film with a certain composition can be deposited by concurrently introducing multiple different kinds of precursors. Alternatively, in the case where multiple different kinds of precursors are introduced, a film with a certain composition can be deposited by controlling the number of cycles of each of the precursors.

First, a substrate (not illustrated) is prepared, and the insulator 20 is formed over the substrate (see FIG. 12A to FIG. 12D). The insulator 20 is preferably deposited by a sputtering method. By using a sputtering method that does not necessarily use a molecule containing hydrogen as a deposition gas, the hydrogen concentration in the insulator 20 can be reduced. Without limitation to a sputtering method, the insulator 20 may be deposited by a CVD method, an MBE method, a PLD method, an ALD method, or the like as appropriate.

As the insulator 20, silicon nitride is deposited by a pulsed DC sputtering method using a silicon target in an atmosphere containing a nitrogen gas, for example. The use of the pulsed DC sputtering method can inhibit generation of particles due to arcing on the target surface, enabling more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen contained in a layer below the insulator 20 to the above. When an insulator through which copper is less likely to pass, such as silicon nitride, is used as the insulator 20, even in the case where a metal that is likely to diffuse, such as copper, is used for a conductor in a layer (not illustrated) below the insulator 20, upward diffusion of the metal through the insulator 20 can be inhibited.

Alternatively, as the insulator 20, hafnium oxide is deposited by an ALD method, for example. It is particularly preferable to use a method for forming hafnium oxide with a reduced hydrogen concentration.

Next, an oxide film to be the oxide 30 is formed over the insulator 20. The oxide film can be deposited by a sputtering method, a CVD method, an MBE method, a PLD method, an ALD method, or the like. In this embodiment, the deposition of the oxide film is performed by a sputtering method.

In the case where the oxide film is deposited by a sputtering method, oxygen or a mixed gas of oxygen and a noble gas is used as a sputtering gas. Increasing the proportion of oxygen contained in the sputtering gas can increase the amount of excess oxygen in the deposited oxide film. In the case where the oxide film is deposited by a sputtering method, the above In-M-Zn oxide target or the like can be used.

In the case where the oxide film is deposited by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film is deposited by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that the oxide film is preferably formed by appropriate selection of deposition conditions and the atomic ratio to have characteristics required for the oxide 30.

Next, heat treatment is preferably performed. The heat treatment can be performed in a temperature range where the oxide film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure.

Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the oxide film and the like as much as possible.

In this embodiment, the heat treatment is performed at 400° C. for one hour with the flow rate ratio of nitrogen gas to oxygen gas being 4:1. By the heat treatment using the oxygen gas, impurities such as carbon, water, and hydrogen in the oxide film can be reduced, for example. Furthermore, the reduction of impurities in the films improves the crystallinity of the oxide film, thereby offering a dense structure with higher density. Thus, crystalline regions in the oxide film are expanded, so that in-plane variations of the crystalline regions in the oxide film can be reduced. Accordingly, an in-plane variation of electrical characteristics of the transistor 10 can be reduced.

Next, the oxide film is processed into an island shape or a band shape by a lithography method to form the oxide 30 (see FIG. 12A to FIG. 12D). Note that in this specification and the like, the term “island shape or band shape” refers to a state where two or more layers formed using the same material in the same step are physically separated from each other. A dry etching method or a wet etching method can be used for the processing. A dry etching method is suitable for microfabrication.

Note that in the lithography method, first, a resist is exposed to light through a mask. Next, a region exposed to light is removed or left using a developing solution, so that a resist mask is formed. Then, etching process through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with liquid (e.g., water) in light exposure. Alternatively, an electron beam or an ion beam may be used instead of the light. Note that a mask is unnecessary in the case of using an electron beam or an ion beam. Note that the resist mask can be removed by a dry etching process such as ashing, a wet etching process, a wet etching process after a dry etching process, or a dry etching process after a wet etching process.

In addition, a hard mask formed of an insulator or a conductor may be used under the resist mask. In the case where a hard mask is used, a hard mask with a desired shape can be formed by forming an insulating film or a conductive film to be a hard mask material over the oxide film, forming a resist mask thereover, and then etching the hard mask material. The etching of the oxide film may be performed after removing the resist mask or with the resist mask remaining. In the latter case, the resist mask sometimes disappears during the etching. The hard mask may be removed by etching after the etching of the oxide film. Meanwhile, the hard mask is not necessarily removed when the hard mask material does not affect later steps or can be utilized in later steps.

Note that FIG. 12C and FIG. 12D each illustrate a structure where the side surface of the oxide 30 is substantially perpendicular to the top surface of the insulator 20. With such a structure, the plurality of transistors 10 can be provided with high density in a small area.

Without limited to the above, the side surface of the oxide 30 may have a tapered shape. The oxide 30 has a taper angle greater than or equal to 60° and less than 90°, for example. When the side surface has a tapered shape in such a manner, the coverage with an insulating film to be the insulator 35a and the insulator 35b (an insulating film 35A described later) can be improved in a later step, so that the number of defects such as voids can be reduced.

Next, the oxide film 35A is formed over the oxide 30 (see FIG. 12A to FIG. 12D). The insulating film 35A can be deposited by a sputtering method, a CVD method, an MBE method, a PLD method, an ALD method, or the like. A silicon oxide film may be deposited by a sputtering method as the insulating film 35A, for example. When the insulating film 35A is deposited by a sputtering method in an oxygen-containing atmosphere, the insulating film 35A containing excess oxygen can be formed. Since a molecule containing hydrogen is not used as a deposition gas in the sputtering method, the concentration of hydrogen in the insulating film 35A can be reduced. Note that heat treatment may be performed before the insulating film 35A is deposited. The heat treatment may be performed under reduced pressure, and the insulating film 35A may be successively deposited without exposure to the air. By performing such treatment, the moisture concentration and the hydrogen concentration in the oxide 30 can be reduced. For the heat treatment, the above heat treatment conditions can be used.

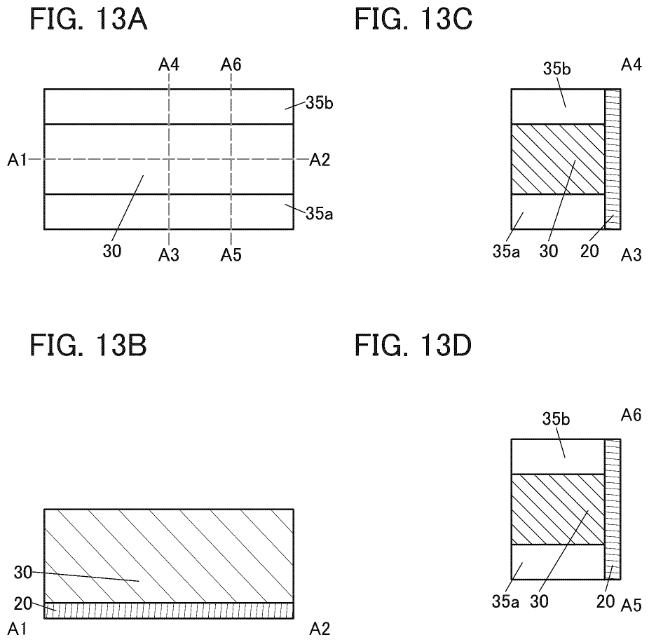

Next, the insulating film 35A is polished by CMP treatment until the oxide 30 is exposed, whereby the insulator 35a and the insulator 35b having flat top surfaces are formed (see FIG. 13A to FIG. 13D). Note that silicon nitride may be deposited over the oxide 30, the insulator 35a, and the insulator 35b by a sputtering method, for example, and CMP treatment may be performed until the silicon nitride reaches the oxide 30, the insulator 35a, and the insulator 35b.

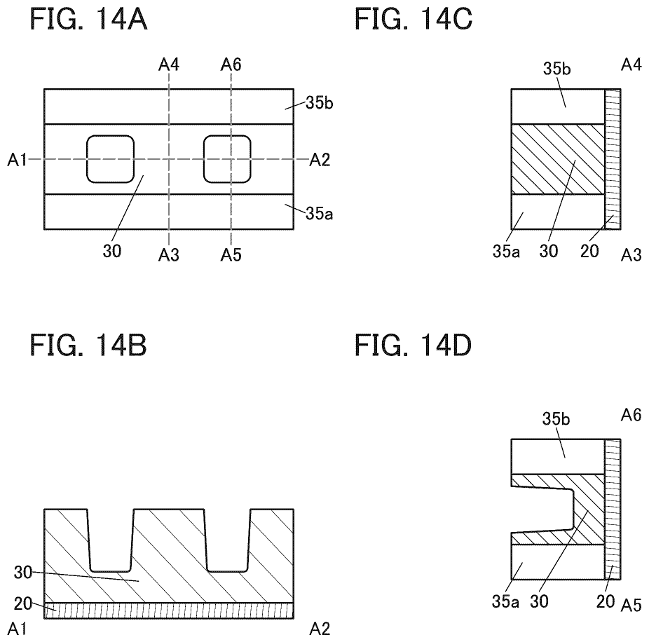

Subsequently, a first depressed portion and a second depressed portion are formed in the oxide 30 (see FIG. 14A to FIG. 14D). Wet etching may be used for the formation of the opening; however, dry etching is preferably used for microfabrication.

As a dry etching apparatus, a capacitively coupled plasma (CCP) etching apparatus having parallel plate electrodes can be used. The capacitively coupled plasma etching apparatus having the parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus having a high-density plasma source can be used. As the dry etching apparatus having a high-density plasma source, an inductively coupled plasma (ICP) etching apparatus or the like can be used, for example.

As illustrated in FIG. 5, in the case where the first depressed portion and the second depressed portion are formed to reach the insulator 20, an insulator functioning as an etching stopper film when the oxide 30 is etched to form an opening is preferably selected as the insulator 20.

Next, a conductive film to be the conductor 42a and the conductor 42b is formed. The conductive film can be deposited by a sputtering method, a CVD method, an MBE method, a PLD method, an ALD method, or the like. For example, for the conductive film, tantalum nitride may be deposited by a sputtering method. Note that heat treatment may be performed before the conductive film is formed. This heat treatment may be performed under reduced pressure, and the conductive film may be successively formed without exposure to the air. Such treatment can remove moisture and hydrogen adsorbed onto the surface of the oxide 30, and further can reduce the moisture concentration and the hydrogen concentration in the oxide 30. The heat treatment is preferably performed at a temperature higher than or equal to 100° C. and lower than or equal to 400° C. For example, the heat treatment is performed at 200° C.

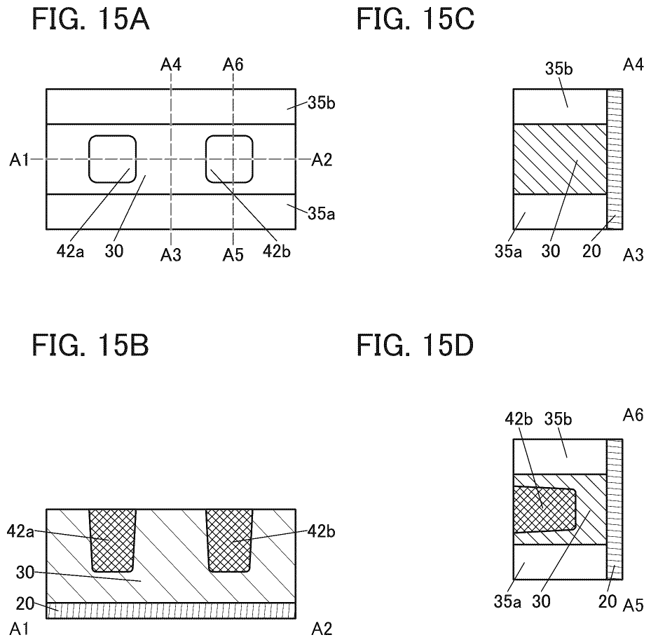

Next, CMP treatment is performed to remove part of the conductive film to be the conductor 42a and the conductor 42b, so that the oxide 30, the insulator 35a, and the insulator 35b are exposed (see FIG. 15A to FIG. 15D). As a result, the conductor 42a remains in the first depressed portion, and the conductor 42b remains in the second depressed portion. Note that the oxide 30, the insulator 35a, and the insulator 35b are partly removed by the CMP treatment in some cases.

Then, a conductive film to be the conductor 46a and the conductor 46b is formed. The conductive film can be deposited by a sputtering method, a CVD method, an MBE method, a PLD method, an ALD method, or the like.

Next, the conductive film to be the conductor 46a and the conductor 46b is processed by a lithography method to form the conductor 46a in contact with at least part of the top surface of the conductor 42a and the conductor 46b in contact with at least part of the top surface of the conductor 42b. At this time, part of the oxide 30, part of the insulator 35a, and part of the insulator 35b that are in regions overlapping with neither the conductor 46a nor the conductor 46b is removed in some cases.

Then, an insulating film to be the insulator 80 is formed over the oxide 30, the conductor 42a, the conductor 42b, the insulator 35a, the insulator 35b, the conductor 46a, and the conductor 46b. The insulating film can be deposited by a sputtering method, a CVD method, an MBE method, a PLD method, an ALD method, or the like. A silicon oxide film may be deposited by a sputtering method as the insulating film, for example. When the insulating film is deposited by a sputtering method in an oxygen-containing atmosphere, the insulator 80 containing excess oxygen can be formed. By using a sputtering method that does not necessarily use a molecule containing hydrogen as a deposition gas, the hydrogen concentration in the insulator 80 can be reduced. Note that heat treatment may be performed before the insulating film is formed. The heat treatment may be performed under reduced pressure, and the insulating film may be successively formed without exposure to the air. Such treatment can remove moisture and hydrogen adsorbed onto the surface of the oxide 30 and the like, and further can reduce the moisture concentration and the hydrogen concentration in the oxide 30, the insulator 35a, and the insulator 35b. For the heat treatment, the above heat treatment conditions can be used.

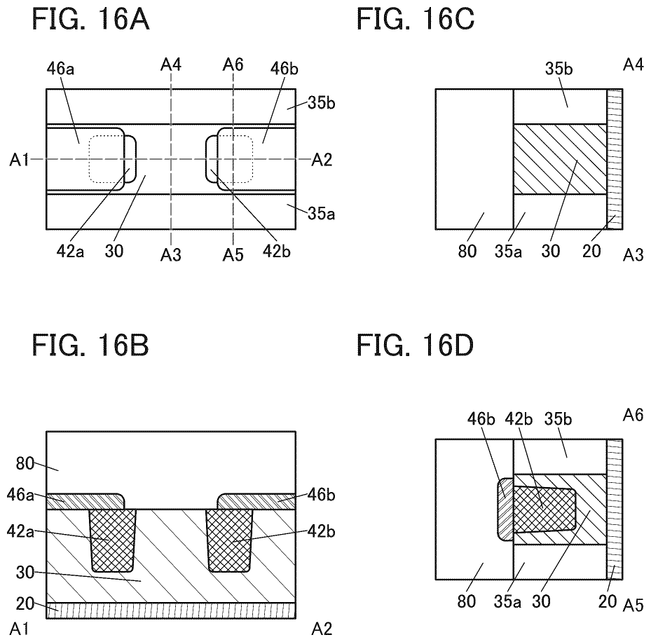

Next, the insulating film to be the insulator 80 is subjected to CMP treatment, so that the insulator 80 with a flat top surface is formed (see FIG. 16A to FIG. 16D). Note that, for example, silicon nitride may be deposited over the insulator 80 by a sputtering method and CMP treatment may be performed on the silicon nitride until the insulator 80 is reached.

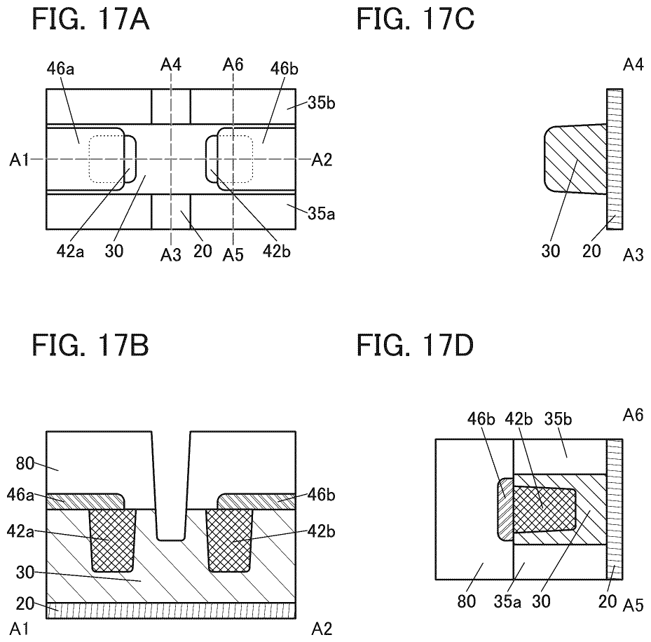

Then, part of the insulator 80 is processed to form an opening reaching the oxide 30 (see FIG. 17A to FIG. 17D). Furthermore, part of the oxide 30 in a region overlapping with the opening is processed, whereby a third depressed portion is formed in the oxide 30. Note that the opening formed in the insulator 80 and the third depressed portion formed in the oxide 30 are collectively referred to as an opening formed in the insulator 80 and the oxide 30 in some cases. As illustrated in FIG. 17A and FIG. 17B, the insulator 35a and the insulator 35b that are in the region overlapping with the opening are removed. In other words, the insulator 35a and the insulator 35b that are in the region overlapping with the opening are removed, so that the insulator 20 is exposed. Note that part of the insulator 35a and part of the insulator 35b in the region overlapping with the opening may remain.

Here, as illustrated in FIG. 17B and FIG. 17C, a side surface of the insulator 80 may have a tapered shape.

A dry etching method or a wet etching method can be used for the processing of part of the insulator 80 and part of the oxide 30. Processing by a dry etching method is suitable for microfabrication. The processing may be performed under different conditions.

In the case where the conductor 25 is provided as illustrated in FIG. 10A to FIG. 10D, the third depressed portion is preferably formed to overlap with the conductor 25.

Here, impurities might be attached onto the top and side surfaces of the oxide 30, the side surface of the insulator 80, and the like or the impurities might be diffused thereinto. A step of removing the impurities may be performed. In addition, a damaged region might be formed on the surface of the oxide 30 by the above dry etching. The damaged region may be removed. The impurities result from components contained in the insulator 80; components contained in a member of an apparatus used to form the opening; and components contained in a gas or a liquid used for etching, for example. Examples of the impurities include hafnium, aluminum, silicon, tantalum, fluorine, and chlorine.

In particular, impurities such as aluminum and silicon might reduce the crystallinity of the oxide 30. Thus, it is preferable that impurities such as aluminum and silicon be removed from the surface of the oxide 30 and the vicinity thereof. The concentration of the impurities is preferably reduced. For example, the concentration of aluminum atoms of the surface of the oxide 30 and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, yet further preferably lower than 0.3 atomic %.

Note that since the density of the crystal structure is reduced in a low-crystallinity region of the oxide 30 owing to impurities such as aluminum and silicon, a large amount of VoH is formed; thus, the transistor is likely to be normally on. Hence, the low-crystallinity region of the oxide 30 is preferably reduced or removed.

In order to remove impurities and the like attached to the surface of the oxide 30 in the above etching step, cleaning treatment is performed. Examples of the cleaning method include wet cleaning using a cleaning solution or the like (also referred to as wet etching treatment), plasma treatment using plasma, and cleaning by heat treatment, and any of these cleanings may be performed in appropriate combination. Note that the cleaning treatment sometimes makes the third depressed portion deeper.

The cleaning treatment may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution may be adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 30 and the like can be reduced when such a frequency is used.

The cleaning treatment may be performed a plurality of times, and the cleaning solution may be changed in every cleaning treatment. For example, the first cleaning treatment may use diluted hydrofluoric acid or diluted ammonia water and the second cleaning treatment may use pure water or carbonated water.

As the cleaning treatment in this embodiment, wet cleaning using diluted ammonia water is performed. The cleaning treatment can remove impurities that are attached onto the surfaces of the oxide 30 and the like or diffused into the oxide 30 and the like. Furthermore, the crystallinity of the oxide 30 can be increased.

After the etching or the cleaning treatment, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 30 to reduce oxygen vacancies. In addition, the crystallinity of the oxide 30 can be improved by the heat treatment. The heat treatment may be performed under reduced pressure. Alternatively, heat treatment may be performed in an oxygen atmosphere, and then heat treatment may be successively performed in a nitrogen atmosphere without exposure to the air.

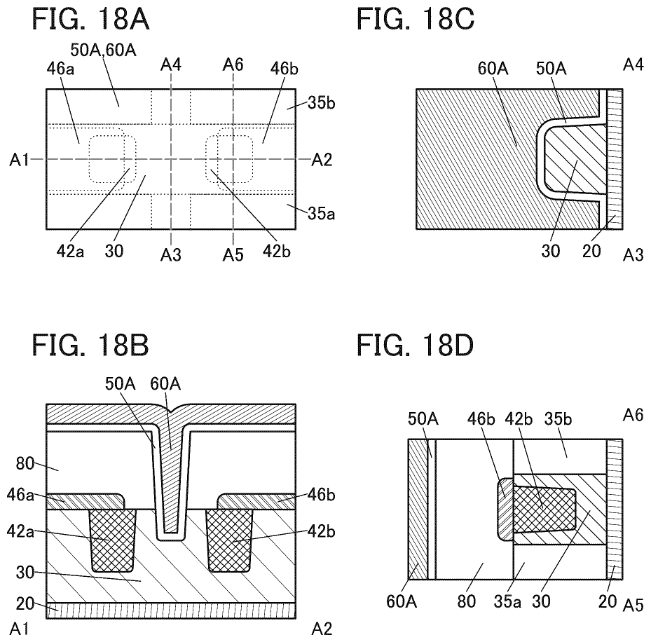

Next, an insulating film 50A is formed (see FIG. 18A to FIG. 18D). Heat treatment may be performed before the formation of the insulating film 50A; the heat treatment may be performed under reduced pressure, and the insulating film 50A may be successively formed without exposure to the air. The heat treatment is preferably performed in an oxygen-containing atmosphere. Such treatment can remove moisture and hydrogen adsorbed onto the surface of the oxide 30 and the like, and further can reduce the moisture concentration and the hydrogen concentration in the oxide 30. The heat treatment is preferably performed at a temperature higher than or equal to 100° C. and lower than or equal to 400° C.

The insulating film 50A can be deposited by a sputtering method, a CVD method, a PECVD method, an MBE method, a PLD method, an ALD method, or the like. The insulating film 50A is preferably formed by a formation method using a gas in which hydrogen atoms are reduced or removed. This can reduce the hydrogen concentration in the insulating film 50A. The hydrogen concentration in the insulating film 50A is suitably reduced because the insulating film 50A becomes the insulator 50 that is in contact with the oxide 30 in a later step.

In this embodiment, silicon oxynitride is deposited for the insulating film 50A by a PECVD method. In addition, silicon oxide is deposited for the insulating film 50A by an ALD method.

Next, it is preferable to perform microwave treatment in an atmosphere containing oxygen. Here, the microwave treatment refers to, for example, treatment using an apparatus including a power source that generates high-density plasma with the use of a microwave. Note that in this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. A power source may be provided to the microwave treatment apparatus to apply RF to the substrate side. Furthermore, application of RF to the substrate side allows oxygen ions generated by the high-density plasma to be introduced into the oxide 30 efficiently.

The microwave treatment is preferably performed under reduced pressure, and the pressure may be higher than or equal to 10 Pa and lower than or equal to 1000 Pa, preferably higher than or equal to 300 Pa and lower than or equal to 700 Pa. The treatment temperature may be lower than or equal to 750° C., preferably lower than or equal to 500° C., and is approximately 250° C., for example. The oxygen plasma treatment can be followed successively by heat treatment without exposure to air. For example, the heat treatment may be performed at higher than or equal to 100° C. and lower than or equal to 750° C., preferably higher than or equal to 300° C. and lower than or equal to 500° C.

Furthermore, the microwave treatment is preferably performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the region 30i illustrated in FIG. 2 can be reduced by thus performing the microwave treatment in an atmosphere containing oxygen. In addition, the carrier concentrations in the region 30n1 and the region 30n2 illustrated in FIG. 2 can be prevented from being excessively reduced by preventing an excess amount of oxygen from being introduced into the chamber in the microwave treatment.

By performing the microwave treatment in an oxygen-containing atmosphere, the high-frequency wave such as a microwave or RF, oxygen plasma, or the like can act on the region 30i illustrated in FIG. 2. The effect of the plasma, the microwave, or the like enables VOH in the region 30i to be cut, and hydrogen to be removed from the region 30i. That is, VoH contained in the region 30i can be reduced. As a result, oxygen vacancies and VoH in the region 30i can be reduced to lower the carrier concentration. In addition, oxygen radicals generated by the oxygen plasma or oxygen contained in the insulating film 50A can be supplied to oxygen vacancies formed in the region 30i, thereby further reducing oxygen vacancies and lowering the carrier concentration in the region 30i.

Furthermore, the film quality of the insulator 50 can be improved, leading to higher reliability of the transistor 10.

In the microwave treatment, thermal energy is directly transmitted to the oxide 30 in some cases owing to an electromagnetic interaction between the microwave and a molecule in the oxide 30. The oxide 30 may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the oxide 30, it is probable that the thermal energy is transmitted to the hydrogen in the oxide 30 and the hydrogen activated by the energy is released from the oxide 30.

After the microwave treatment, heat treatment may be performed with the reduced pressure being maintained. Such treatment enables hydrogen in the insulating film 50A and the oxide 30 to be removed efficiently. Some hydrogen may be gettered into the conductor 42a and the conductor 42b in some cases. Alternatively, the step of performing microwave treatment and then performing heat treatment with the reduced pressure being maintained may be repeated a plurality of cycles. The repetition of the heat treatment enables hydrogen in the insulating film 50A and the oxide 30 to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 30 and the like are adequately heated by the microwave annealing.

Furthermore, the microwave treatment improves the film quality of the insulating film 50A, thereby inhibiting diffusion of hydrogen, water, impurities, and the like. Accordingly, hydrogen, water, impurities, and the like can be inhibited from diffusing into the oxide 30 through the insulator 50 in a later step such as formation of the conductive film to be the conductor 60 or later treatment such as heat treatment.

In the case where the insulator 50 has a stacked-layer structure of three layers illustrated in FIG. 11B, an insulating film to be the insulator 50a is formed before the formation of the insulating film 50A, and an insulating film to be the insulator 50c is formed after the formation of the insulating film 50A. In this case, the insulating film 50A can be rephrased as an insulating film to be the insulator 50b. The insulating film to be the insulator 50a and the insulating film to be the insulator 50c can each be independently deposited by a sputtering method, a CVD method, an MBE method, a PLD method, an ALD method, or the like.

The insulating film to be the insulator 50a is preferably deposited using an ALD method. As described above, it is preferable to form the insulating film to have a small thickness, and an unevenness of the thickness needs to be reduced. In contrast, an ALD method is a deposition method in which a precursor and a reactant (e.g., oxidizer) are alternately introduced, and the film thickness can be adjusted with the number of repetition times of the cycle; thus, accurate control of the film thickness is possible. Furthermore, as illustrated in FIG. 11B and FIG. 11C, the insulating film needs to be formed on the bottom surface and the side surface of the opening formed in the insulator 80 and the oxide 30 so as to have good coverage. In particular, it is preferable that the insulating film be formed on the top surface and the side surface of the oxide 30 with good coverage. An atomic layer can be deposited one by one on the bottom surface and the side surface of the opening, whereby the insulating film can be formed in the opening with good coverage.

When the insulating film to be the insulator 50a is deposited by an ALD method, ozone (O₃), oxygen (O₂), water (H₂O), or the like can be used as the oxidizer. When ozone (O₃), oxygen (O₂), or the like, which does not contain hydrogen, is used as the oxidizer, the amount of hydrogen diffusing into the oxide 30 can be reduced.

In this embodiment, aluminum oxide is deposited as the insulating film to be the insulator 50a by a thermal ALD method.

The insulating film to be the insulator 50c is preferably deposited by an ALD method like the insulating film to be the insulator 50a. By an ALD method, the insulating film to be the insulator 50c can be deposited to have a small thickness and good coverage. In this embodiment, silicon nitride is deposited by a PEALD method as the insulating film to be the insulator 50c.

In the case where the insulator 50 has a stacked-layer structure of three layers illustrated in FIG. 11B, the microwave treatment is preferably performed after the insulating film to be the insulator 50a is formed or after the insulating film to be the insulator 50b is formed.

Next, a conductive film 60A is formed (see FIG. 18A to FIG. 18D). The conductive film 60A can be deposited by a sputtering method, a CVD method, an MBE method, a PLD method, an ALD method, or the like. In the case where the conductor 60 has a stacked-layer structure of two layers illustrated in FIG. 11B, for example, titanium nitride is deposited as a conductive film to be the conductor 60a by an ALD method and tungsten is deposited as a conductive film to be the conductor 60b by a CVD method.

Then, the insulating film 50A and the conductive film 60A are polished by CMP treatment until the insulator 80 is exposed, whereby the insulator 50 and the conductor 60 are formed (see FIG. 1A to FIG. 1D). Accordingly, the insulator 50 is provided to cover the openings formed in the insulator 80 and the oxide 30. The conductor 60 is provided to fill the opening with the insulator 50 therebetween.

Next, heat treatment may be performed under conditions similar to those for the above heat treatment. In this embodiment, treatment is performed at 400° C. in a nitrogen atmosphere for one hour. The heat treatment can reduce the moisture concentration and the hydrogen concentration in the insulator 50 and the insulator 80. After the heat treatment, an insulator described later may be formed successively without exposure to the air.

Subsequently, an insulator (not illustrated in FIG. 1A to FIG. 1D) is formed over the insulator 50, the conductor 60, and the insulator 80. The insulator can be deposited by a sputtering method, a CVD method, an MBE method, a PLD method, an ALD method, or the like. The insulator is preferably deposited by a sputtering method. By using a sputtering method that does not necessarily use a molecule containing hydrogen as a deposition gas, the hydrogen concentration in the insulator can be reduced.

As the insulator, aluminum oxide is preferably deposited by a pulsed DC sputtering method using an aluminum target in an atmosphere containing an oxygen gas, for example. The use of the pulsed DC sputtering method can achieve more uniform film thickness and improve the sputtering rate and film quality. The RF power applied to the substrate is lower than or equal to 1.86 W/cm². The RF power applied to the substrate is preferably greater than or equal to 0 W/cm² and less than or equal to 0.62 W/cm². With low RF power, the amount of oxygen implanted to the insulator 80 can be reduced.

The insulator is deposited by a sputtering method in an oxygen-containing atmosphere, whereby oxygen can be added to the insulator 80 during the deposition. Thus, excess oxygen can be contained in the insulator 80. At this time, the insulator is preferably formed while the substrate is being heated.

Through the above processes, the semiconductor device including the transistor 10 illustrated in FIG. 1A to FIG. 1D can be manufactured. As illustrated in FIG. 12A to FIG. 18D, the transistor 10 can be manufactured with the use of the method for manufacturing the semiconductor device described in this embodiment.

### Manufacturing Method Example 2

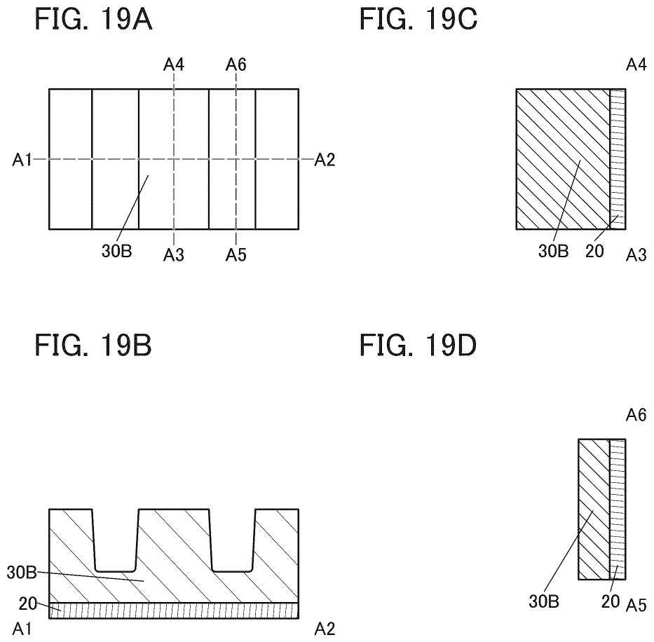

A method for manufacturing the semiconductor device including the transistor 10 illustrated in FIG. 4C and FIG. 4D exemplified in Structure Example 1 is described below with reference to FIG. 19A to FIG. 22D.

Note that A of each drawing illustrates a top view. Moreover, B of each drawing is a cross-sectional view corresponding to a portion indicated by the dashed-dotted line A1-A2 in A of each drawing, and is also a cross-sectional view of the transistor 10 in the channel length direction. Furthermore, C of each drawing is a cross-sectional view corresponding to a portion indicated by the dashed-dotted line A3-A4 in A of each drawing, and is also a cross-sectional view of the transistor 10 in the channel width direction. Furthermore, D of each drawing is a cross-sectional view of a portion indicated by the dashed-dotted line A5-A6 in A of each drawing.

Note that for clarity of the drawing, some components are not illustrated in the top view of A of each drawing.

Note that for the portions similar to those in Manufacturing Method Example 1, the above description is referred to and the repeated description is omitted below, in some cases.

First, a substrate (not illustrated) is prepared and the insulator 20 is formed over the substrate. The insulator 20 can be formed by a method similar to that described above.

Next, an oxide film 30B to be the oxide 30 is formed over the insulator 20. The oxide film 30B can be formed by a method similar to the method for forming the oxide film to be the oxide 30.

Next, two openings are formed in the oxide film 30B (see FIG. 19A to FIG. 19D). Each of the two openings extends in the direction perpendicular to the dashed-dotted line A1-A2 illustrated in FIG. 19A. Wet etching may be used for the formation of the two openings; however, dry etching is preferably used for microfabrication.

Subsequently, the conductive film to be the conductor 42a and the conductor 42b is formed. The conductive film can be formed by a method similar to that described above.

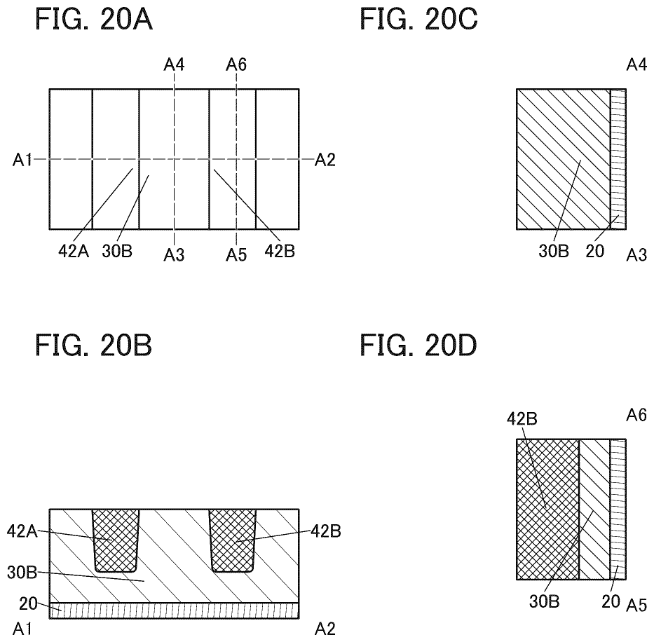

Then, by performing CMP treatment, the conductive film to be the conductor 42a and the conductor 42b is partly removed to expose the oxide film 30B (see FIG. 20A to FIG. 20D). As a result, a conductive layer 42A remains inside one of the two openings, and a conductive layer 42B remains inside the other of the two openings. Note that the oxide film 30B is partly removed by the CMP treatment in some cases.

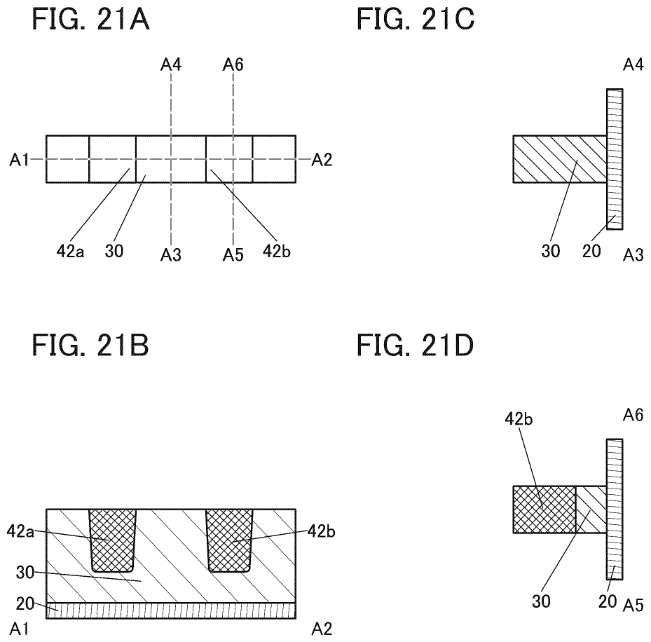

Next, by a lithography method, the oxide film 30B is processed into an island shape or a band shape to form the oxide 30, the conductive layer 42A is processed into an island shape to form the conductor 42a, and the conductive layer 42B is processed into an island shape to form the conductor 42b (see FIG. 21A to FIG. 21D). A dry etching method or a wet etching method can be used for the processing. A dry etching method is suitable for microfabrication.

Then, the insulating film to be the insulator 35a and the insulator 35b is formed over the oxide 30, the conductor 42a, and the conductor 42b. The insulating film can be formed by a method similar to the method for forming the insulating film 35A.

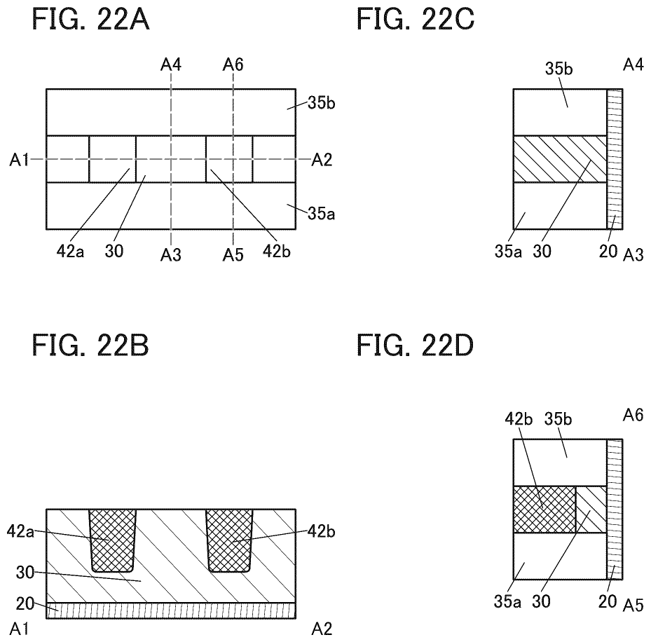

Next, the insulating film is polished by CMP treatment until the oxide 30 is exposed, whereby the insulator 35a and the insulator 35b having flat top surfaces are formed (see FIG. 22A to FIG. 22D).

Subsequently, the conductor 46a and the conductor 46b are formed. The conductor 46a and the conductor 46b can be formed by a method similar to that described above.

Next, the insulator 80 is formed. The insulator 80 can be formed by a method similar to that described above.

Then, the insulator 50 and the conductor 60 are formed. The insulator 50 and the conductor 60 can be formed by a method similar to that described above.

Through the above processes, the semiconductor device including the transistor 10 illustrated in FIG. 4C and FIG. 4D can be manufactured. As illustrated in FIG. 19A to FIG. 22D, the transistor 10 can be manufactured with the use of the method for manufacturing the semiconductor device described in this embodiment.

### <Microwave Treatment Apparatus>

A microwave treatment apparatus that can be used for the above method for manufacturing the semiconductor device is described below.

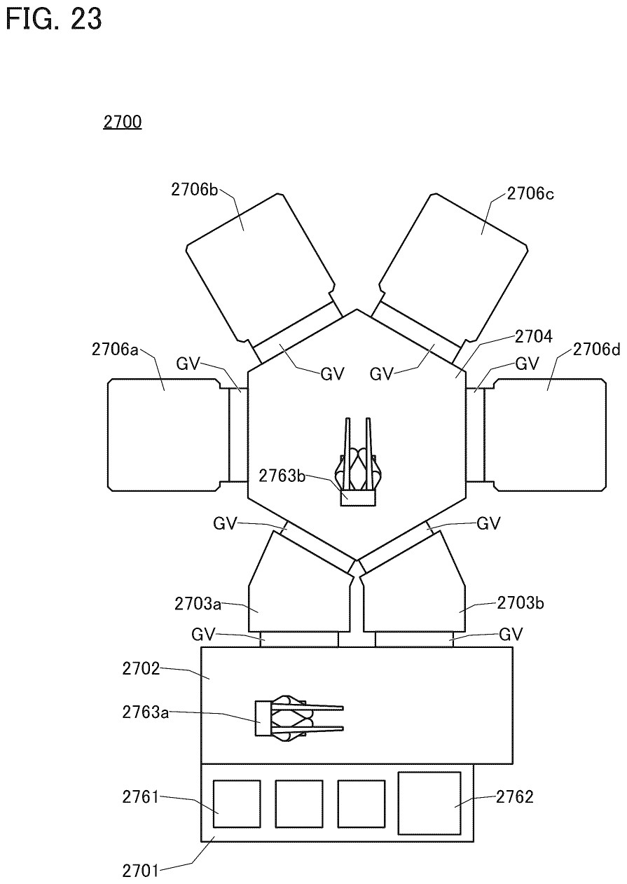

First, a structure of a manufacturing apparatus that hardly allows entry of impurities in manufacturing a semiconductor device or the like is described with reference to FIG. 23 to FIG. 26.

FIG. 23 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like.

Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate can be derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, a metal covered with iron fluoride, aluminum oxide, or chromium oxide is preferably used. The metal gasket achieves higher adhesion than an O-ring and can reduce the external leakage. Furthermore, with the use of a passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only a metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a noble gas is preferably used as the inert gas.

Alternatively, treatment for evacuating the transfer chamber 2704 and each of the chambers is preferably performed again a certain period of time after a heated inert gas such as a noble gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa in the time range of 1 minute to 300 minutes, preferably 5 minutes to 120 minutes. After that, the transfer chamber 2704 and each of the chambers are evacuated in the time range of 5 minutes to 300 minutes, preferably 10 minutes to 120 minutes.

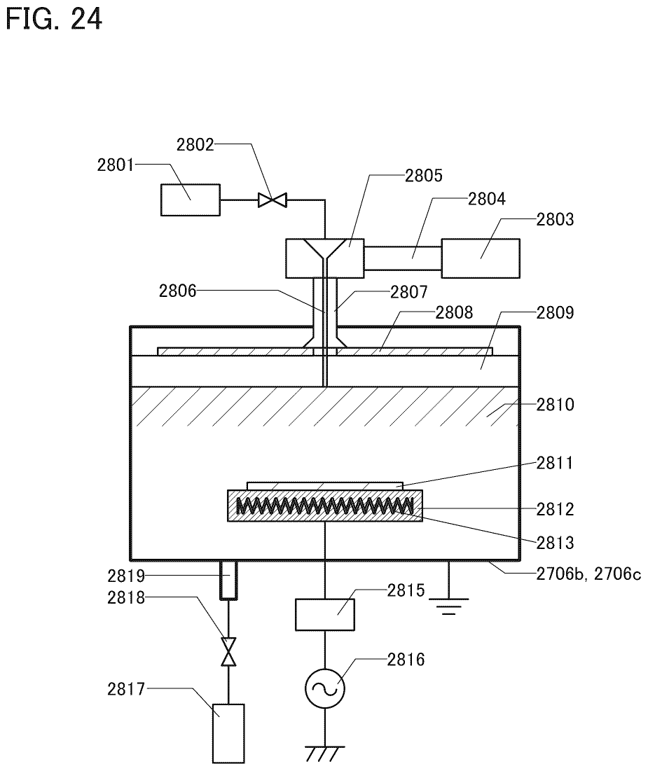

Next, the chamber 2706b and the chamber 2706c are described with reference to a schematic cross-sectional view illustrated in FIG. 24.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The use of the cryopump and the cryotrap is particularly preferable because water can be efficiently exhausted.

Furthermore, for example, the heating mechanism 2813 may be a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is −80° C. or lower, preferably −100° C. or lower is preferably used. For example, an oxygen gas, a nitrogen gas, or a noble gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, higher than or equal to 0.3 GHz and lower than or equal to 3.0 GHZ, higher than or equal to 0.7 GHZ and lower than or equal to 1.1 GHz, or higher than or equal to 2.2 GHz and lower than or equal to 2.8 GHz. The microwave generated by the high-frequency generator 2803 is propagated to the mode converter 2805 through the waveguide 2804. The mode converter 2805 converts the microwave propagated in the TE mode into a microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like may be used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

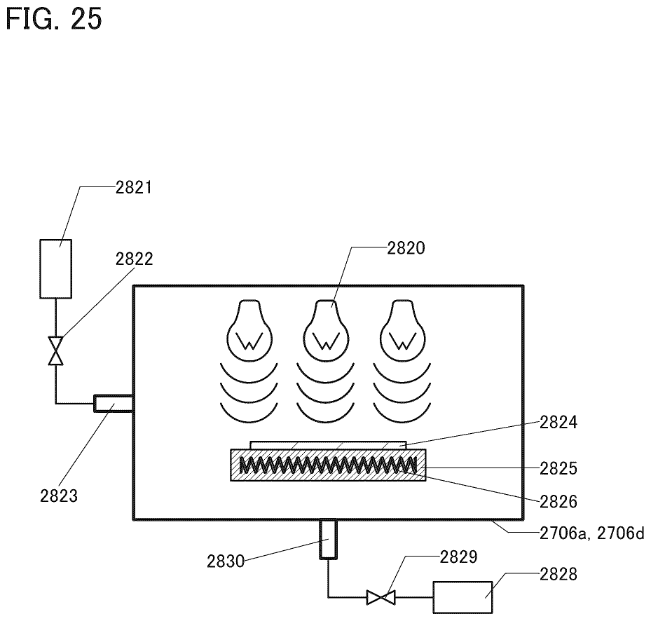

Next, the chamber 2706a and the chamber 2706d are described with reference to a schematic cross-sectional view illustrated in FIG. 25.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is placed to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light may be used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm may be used.

As the lamp 2820, a light source such as a halogen lamp, a metal halide lamp, a xenon arc lamp, a carbon arc lamp, a high-pressure sodium lamp, or a high-pressure mercury lamp can used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not necessarily include the heating mechanism 2826 therein.

For the vacuum pump 2828, refer to the description of the vacuum pump 2817.

Furthermore, for the heating mechanism 2826, refer to the description of the heating mechanism 2813. Furthermore, for the gas supply source 2821, refer to the description of the gas supply source 2801.

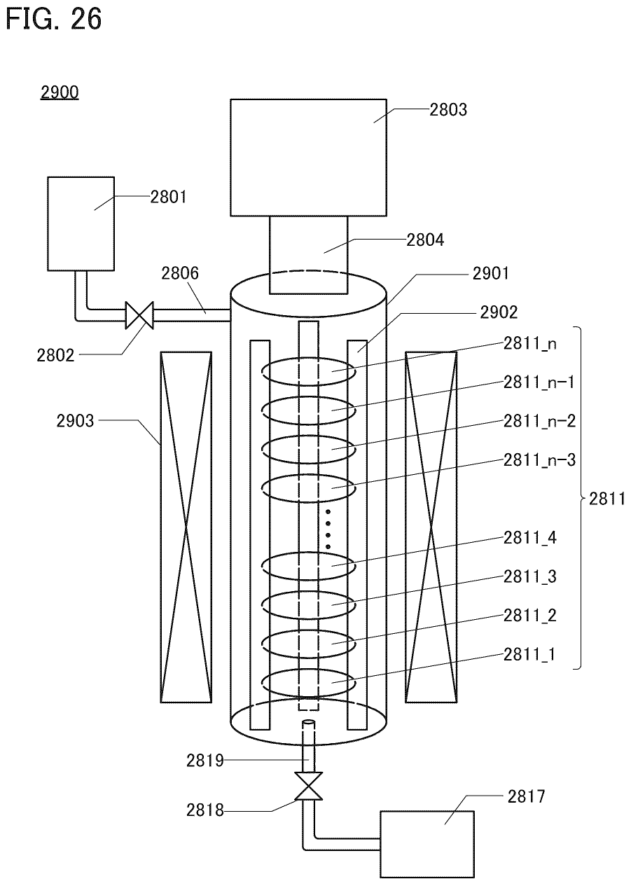

A microwave treatment apparatus that can be used in this embodiment is not limited to the above. A microwave treatment apparatus 2900 illustrated in FIG. 26 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With the use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With the use of the above-described manufacturing apparatus, the quality of a film or the like can be modified while the entry of impurities into an object is inhibited.

### <Variation Example of Semiconductor Device>

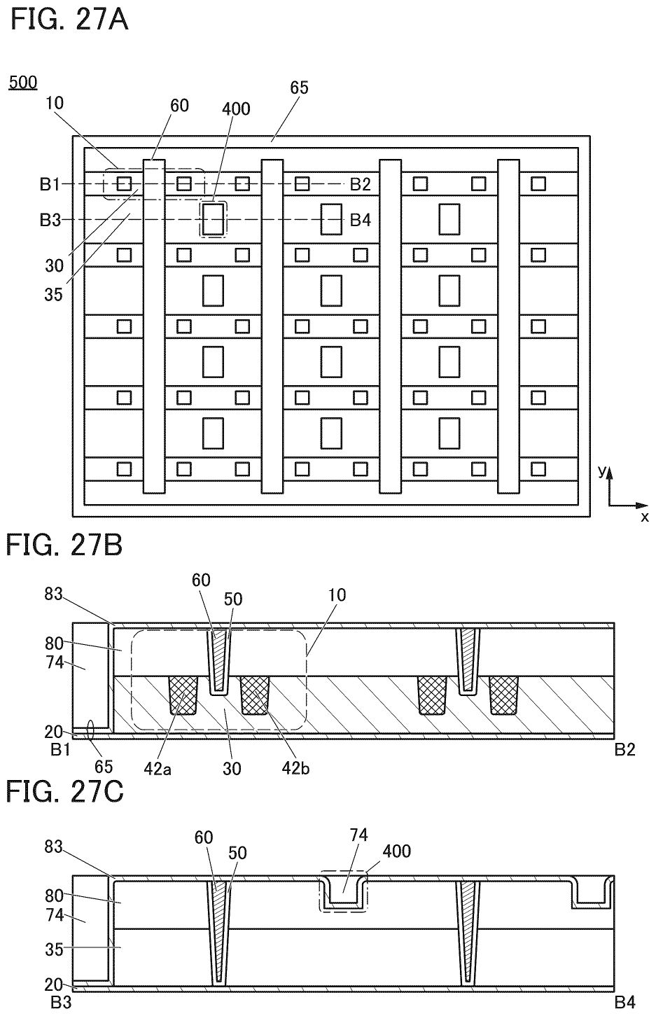

Examples of the semiconductor device of one embodiment of the present invention are described below with reference to FIG. 27A to FIG. 27C.

FIG. 27A is a top view of a semiconductor device 500. In FIG. 27A, the x direction is parallel to the channel length direction of the transistor 10, and the y direction is perpendicular to the x direction. FIG. 27B is a cross-sectional view corresponding to a portion indicated by the dashed-dotted line B1-B2 in FIG. 27A, and is also a cross-sectional view of the transistor 10 in the channel length direction. FIG. 27C is a cross-sectional view corresponding to a portion indicated by the dashed-dotted line B3-B4 in FIG. 27A, and is also a cross-sectional view of an opening region 400 and its vicinity. Note that some components are omitted in the top view of FIG. 27A for clarity of the drawing.

Note that in the semiconductor device illustrated in FIG. 27A to FIG. 27C, components having the same functions as the components included in the semiconductor device described in the above structure example are denoted by the same reference numerals. Note that the materials described in detail in the above structure example can be used as component materials of the semiconductor devices also in this section.

The semiconductor device 500 illustrated in FIG. 27A to FIG. 27C is a variation example of the semiconductor device illustrated in FIG. 1A to FIG. 1D. The semiconductor device 500 illustrated in FIG. 27A to FIG. 27C is different from the semiconductor device illustrated in FIG. 1A to FIG. 1D in that an insulator 83 and an insulator 74 are included. The semiconductor device 500 illustrated in FIG. 27A to FIG. 27C is different from the semiconductor device illustrated in FIG. 1A to FIG. 1D in that the opening region 400 is formed in the insulator 80. Moreover, a sealing portion 65 is formed to surround the plurality of transistors 10, which is a different point from the semiconductor device illustrated in FIG. 1A to FIG. 1D.

The semiconductor device 500 includes the plurality of transistors 10 and a plurality of opening regions 400 which are arranged in a matrix. In addition, the plurality of conductors 60 functioning as gate electrodes of the transistors 10 are provided to extend in the y direction. The opening regions 400 are formed in regions not overlapping with the oxide 30 or the conductor 60. The sealing portion 65 is formed so as to surround the plurality of transistors 10, the plurality of conductors 60, and the plurality of opening regions 400. Note that the numbers, the positions, and the sizes of the transistors 10, the conductors 60, and the opening regions 400 are not limited to those illustrated in FIG. 27A and may be set as appropriate in accordance with the design of the semiconductor device 500.

As illustrated in FIG. 27B and FIG. 27C, the sealing portion 65 is provided to surround the plurality of transistors 10. In other words, the insulator 83 is provided to cover the plurality of transistors 10. In the sealing portion 65, the insulator 83 is in contact with the top surface of the insulator 20. Over the sealing portion 65, the insulator 74 is provided over the insulator 83. The top surface of the insulator 74 is substantially level with the uppermost surface of the insulator 83. As the insulator 74, an insulator similar to the insulator 80 can be used.

With such a structure, the plurality of transistors 10 can be surrounded by the insulator 83 and the insulator 20. Here, the insulator 83 and the insulator 20 each preferably function as a barrier insulating film against hydrogen. Thus, as the insulator 83, an insulator similar to the insulator 80 is preferably used. Accordingly, entry of hydrogen contained in the region outside the sealing portion 65 into a region in the sealing portion 65 can be inhibited.

As illustrated in FIG. 27C, the insulator 80 has a groove portion in the opening region 400. The depth of the groove portion of the insulator 80 is less than or equal to the depth at which the top surface of the insulator 35 is exposed and is, for example, approximately greater than or equal to ¼ and less than or equal to ½ of the maximum thickness of the insulator 80.

As illustrated in FIG. 27C, the insulator 83 is in contact with a side surface and the top surface of the insulator 80 inside the opening region 400. Part of the insulator 74 is formed in the opening region 400 to fill the depressed portion formed in the insulator 83 in some cases. At this time, the top surface of the insulator 74 formed in the opening region 400 is substantially level with the uppermost surface of the insulator 83, in some cases.

When heat treatment is performed in such a state that the opening region 400 is formed and the insulator 80 is exposed, part of oxygen contained in the insulator 80 can be made to diffuse outwardly from the opening region 400 while oxygen is supplied to the oxide 30. This enables oxygen to be sufficiently supplied to the region functioning as the channel formation region and its vicinity in the oxide semiconductor layer from the insulator 80 containing oxygen to be released by heating, and also prevents an excess amount of oxygen from being supplied thereto.

At this time, hydrogen contained in the insulator 80 can be bonded to oxygen and released to the outside through the opening region 400. The hydrogen bonded to oxygen is released as water. Thus, the amount of hydrogen contained in the insulator 80 can be reduced, and hydrogen contained in the insulator 80 can be prevented from entering the oxide 30.

In FIG. 27A, the shape of the opening region 400 in the top view is substantially rectangular; however, the present invention is not limited to the shape. For example, the shape of the opening region 400 in the top view can be a rectangular shape, an elliptical shape, a circular shape, a rhombus shape, or a shape obtained by combining any of the above shapes. The area and arrangement interval of the opening regions 400 can be set as appropriate in accordance with the design of the semiconductor device including the transistor 10. For example, in the region where the density of the transistors 10 is low, the area of the opening region 400 may be increased or the arrangement interval of the opening regions 400 may be narrowed. For example, in the region where the density of the transistors 10 is high, the area of the opening region 400 may be decreased, or the arrangement interval of the opening regions 400 may be increased.

According to one embodiment of the present invention, a novel transistor can be provided. According to one embodiment of the present invention, a semiconductor device in which a variation of transistor characteristics is small can be provided. According to one embodiment of the present invention, a semiconductor device with favorable electrical characteristics can be provided. According to one embodiment of the present invention, a semiconductor device with high reliability can be provided. According to one embodiment of the present invention, a semiconductor device with a high on-state current can be provided. According to one embodiment of the present invention, a semiconductor device with a high field-effect mobility can be provided. According to one embodiment of the present invention, a semiconductor device with favorable frequency characteristics can be provided. According to one embodiment of the present invention, a semiconductor device that can be miniaturized or highly integrated can be provided. According to one embodiment of the present invention, a semiconductor device with low power consumption can be provided.

At least part of the structure, method, and the like described in this embodiment can be implemented in appropriate combination with any of those in the other embodiments, the other examples, and the like described in this specification.

### Embodiment 2

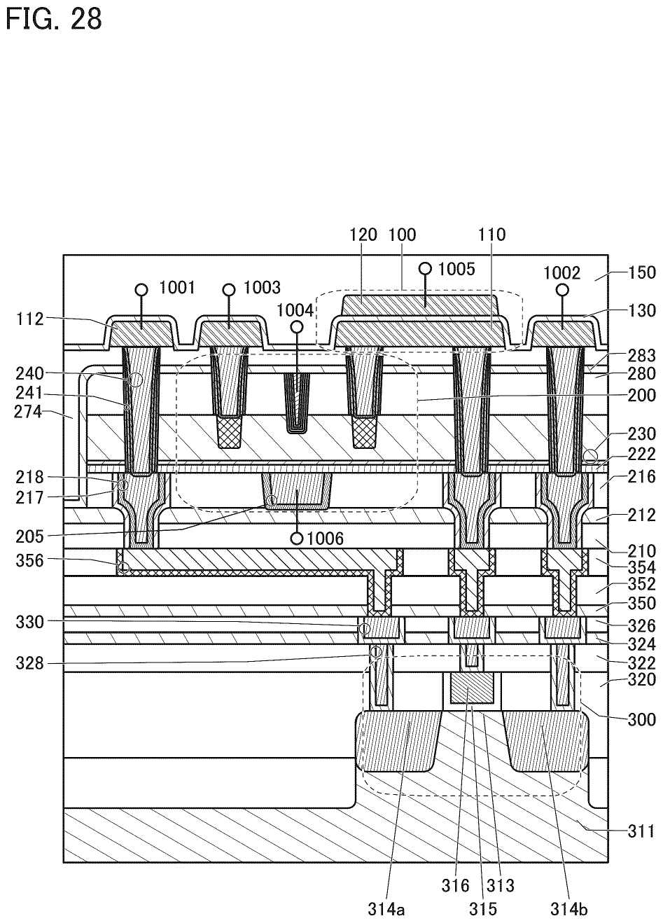

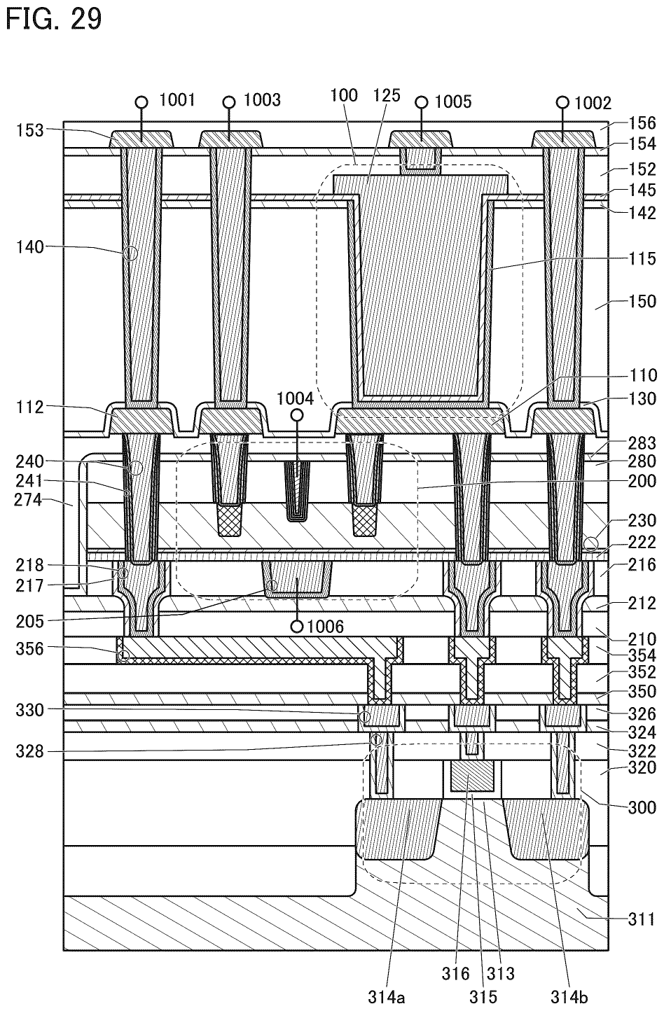

In this embodiment, one embodiment of a semiconductor device will be described with reference to FIG. 28 and FIG. 29. Note that the semiconductor device described in this embodiment can also be referred to as a storage device in some cases. In this specification and the like, a storage device described in this embodiment can be referred to as a semiconductor device because a storage device is one embodiment of a semiconductor device.

### [Storage Device]

FIG. 28 illustrates an example of a storage device of one embodiment of the present invention. In the storage device of one embodiment of the present invention, a transistor 200 is provided above a transistor 300, and a capacitor 100 is provided above the transistor 300 and the transistor 200. The transistor 10 described in the above embodiment can be used as the transistor 200.

The transistor 200 is a transistor in which a channel is formed in a semiconductor layer including an oxide semiconductor. Since the transistor 200 has a low off-state current, a storage device that uses the transistor 200 can retain stored data for a long time. In other words, such a storage device does not require refresh operation or has extremely low frequency of the refresh operation, which leads to a sufficient reduction in power consumption of the storage device.

In the storage device illustrated in FIG. 28, a wiring 1001 is electrically connected to a source of the transistor 300, and a wiring 1002 is electrically connected to a drain of the transistor 300. In addition, a wiring 1003 is electrically connected to one of a source and a drain of the transistor 200, a wiring 1004 is electrically connected to a first gate of the transistor 200, and a wiring 1006 is electrically connected to a second gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The storage device illustrated in FIG. 28 can form a memory cell array when arranged in a matrix.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 28, the semiconductor region 313 (part of the substrate 311) where a channel is formed has a protruding shape. In addition, the conductor 316 is provided to cover a side surface and the top surface of the semiconductor region 313 with the insulator 315 therebetween. Note that a material adjusting the work function may be used as the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 28 is an example and the structure is not limited thereto; an appropriate transistor is used in accordance with a circuit structure or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric. Here, as the insulator 130, the insulator that can be used as the insulator 83 described in the above embodiment is preferably used.

For example, a conductor 112 and the conductor 110 provided over a conductor 240 can be formed at the same time. Note that the conductor 112 functions as a plug or a wiring that is electrically connected to the capacitor 100, the transistor 200, or the transistor 300.

Although the conductor 112 and the conductor 110 having a single-layer structure are illustrated in FIG. 28, a stacked-layer structure of two or more layers may be employed without being limited to the single-layer structure. For example, between a conductor having a barrier property and a conductor having high conductivity, a conductor that is highly adhesive to the conductor having a barrier property and the conductor having high conductivity may be formed.

The insulator 130 can be provided as stacked layers or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, for the insulator 130, a stacked-layer structure of a material with high dielectric strength such as silicon oxynitride and a high dielectric constant (high-k) material is preferably used. In the capacitor 100 having such a structure, a sufficient capacitance can be ensured owing to the high dielectric constant (high-k) insulator, and the dielectric strength can be increased owing to the insulator with high dielectric strength, so that the electrostatic breakdown of the capacitor 100 can be inhibited.

Examples of the high dielectric constant (high-k) material (a material having a high relative dielectric constant) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with high dielectric strength (a material having a low relative dielectric constant) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as a plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 28, an insulator 350, an insulator 352, and an insulator 354 are sequentially stacked. Furthermore, a conductor 356 is formed in the insulator 350, the insulator 352, and the insulator 354. The conductor 356 functions as a plug or a wiring.

Similarly, a conductor 218, a conductor (a conductor 205) included in the transistor 200, and the like are embedded in an insulator 210, an insulator 212, and an insulator 216. Note that the conductor 218 has a function of a plug or a wiring that is electrically connected to the capacitor 100 or the transistor 300. In addition, an insulator 150 is provided over the conductor 120 and the insulator 130.

Here, an insulator 217 is provided in contact with a side surface of the conductor 218 functioning as a plug. The insulator 217 is provided in contact with an inner wall of an opening formed in the insulator 210, the insulator 212, and the insulator 216. That is, the insulator 217 is provided between the conductor 218 and each of the insulator 210, the insulator 212, and the insulator 216. Note that the conductor 205 and the conductor 218 can be formed in parallel; thus, the insulator 217 is sometimes formed in contact with a side surface of the conductor 205.

As the insulator 217, an insulator such as silicon nitride, aluminum oxide, or silicon nitride oxide may be used, for example. Since the insulator 217 is provided in contact with the insulator 210, the insulator 212, and an insulator 222, entry of impurities such as water and hydrogen into the oxide 230 through the conductor 218 from the insulator 210, the insulator 216, or the like can be inhibited. In particular, silicon nitride is suitable because of its high blocking property against hydrogen. Moreover, oxygen contained in the insulator 210 or the insulator 216 can be prevented from being absorbed by the conductor 218.

As the insulator 217, silicon nitride may be deposited by a PEALD method and an opening reaching the conductor 356 may be formed by anisotropic etching, for example.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low relative dielectric constant is used as the insulator functioning as an interlayer film, parasitic capacitance generated between wirings can be reduced. Thus, a material is preferably selected depending on the function of an insulator.

For example, as the insulator 150, the insulator 210, the insulator 352, the insulator 354, and the like, an insulator having a low relative dielectric constant is preferably included. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative dielectric constant. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used as the insulator 212, the insulator 350, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, and the like, a single layer or stacked layers of a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

<Wiring or Plug in Layer Provided with Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, in FIG. 28, an insulator 241 is preferably provided between an insulator 280 containing excess oxygen and the conductor 240. Since the insulator 241 is provided in contact with the insulator 222 and an insulator 283, the transistor 200 can be sealed with the insulators having a barrier property.

That is, the insulator 241 can inhibit excess oxygen contained in the insulator 280 from being absorbed by the conductor 240. In addition, providing the insulator 241 can inhibit diffusion of hydrogen, which is an impurity, into the transistor 200 through the conductor 240.

The insulator 241 is preferably formed using an insulating material having a function of inhibiting diffusion of oxygen and impurities such as water and hydrogen. For example, silicon nitride, silicon nitride oxide, aluminum oxide, hafnium oxide, or the like is preferably used. In particular, silicon nitride is preferable because of its high blocking property against hydrogen. Other than that, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed with the insulator 212 and the insulator 283. Such a structure can inhibit entry of hydrogen contained in an insulator 274, the insulator 150, or the like into the insulator 280 or the like.

Here, the conductor 240 penetrates the insulator 283, and the conductor 218 penetrates the insulator 212; however, as described above, the insulator 241 is provided in contact with the conductor 240, and the insulator 217 is provided in contact with the conductor 218. This can reduce the amount of hydrogen entering the inside of the insulator 212 and the insulator 283 through the conductor 240 and the conductor 218. In this manner, the transistor 200 is sealed with the insulator 212, the insulator 283, the insulator 241, and the insulator 217, so that impurities such as hydrogen contained in the insulator 274 or the like can be inhibited from entering from the outside.

The insulator 212, the insulator 216, the insulator 222, the insulator 280, the insulator 283, and the insulator 274 respectively correspond to the insulator 20, the insulator 16, the insulator 22, the insulator 80, the insulator 83, and the insulator 74 described in the above embodiment. The oxide 230 corresponds to the oxide 30 described in the above embodiment. The conductor 205 corresponds to the conductor 25 described in the above embodiment.

### <Dicing Line>

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate, and then the substrate is cut along the dicing line to divide (split) it into a plurality of semiconductor devices.

Here, for example, as illustrated in FIG. 28, a region in which the insulator 283 and the insulator 212 are in contact with each other is preferably designed to overlap with the dicing line. That is, an opening is provided in the insulator 280, the oxide 230, the insulator 222, and the insulator 216 in the vicinity of a region to be the dicing line that is provided on an outer edge of the memory cell including a plurality of transistors 200.

That is, in the opening provided in the insulator 280, the oxide 230, the insulator 222, and the insulator 216, the insulator 212 is in contact with the insulator 283. Here, the insulator 212 and the insulator 283 may be formed using the same material and the same method. When the insulator 212 and the insulator 283 are formed using the same material and the same method, the adhesion therebetween can be increased. For example, silicon nitride is preferably used.

With the structure, the transistors 200 can be surrounded by the insulator 212 and the insulator 283. Since at least one of the insulator 212 and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the side surface direction of the divided substrate into the transistor 200 can be prevented.

With the structure, excess oxygen in the insulator 280 can be prevented from diffusing to the outside. Accordingly, excess oxygen in the insulator 280 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

Note that although the capacitor 100 of the storage device illustrated in FIG. 28 has a planar shape, the storage device described in this embodiment is not limited thereto. For example, the capacitor 100 may have a cylindrical shape as illustrated in FIG. 29. Note that the structure below and including the insulator 150 of a storage device illustrated in FIG. 29 is similar to that of the storage device illustrated in FIG. 28.

The capacitor 100 illustrated in FIG. 29 includes the insulator 150 over the insulator 130, an insulator 142 over the insulator 150, a conductor 115 placed in an opening formed in the insulator 150 and the insulator 142, an insulator 145 over the conductor 115 and the insulator 142, a conductor 125 over the insulator 145, and an insulator 152 over the conductor 125 and the insulator 145. Here, at least parts of the conductor 115, the insulator 145, and the conductor 125 are placed in the opening formed in the insulator 150 and the insulator 142.

The conductor 115 functions as a lower electrode of the capacitor 100, the conductor 125 functions as an upper electrode of the capacitor 100, and the insulator 145 functions as a dielectric of the capacitor 100. The capacitor 100 has a structure in which the upper electrode and the lower electrode face each other with the dielectric interposed therebetween on the side surface as well as the bottom surface of the opening in the insulator 150 and the insulator 142; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the storage device.

An insulator that can be used as the insulator 280 can be used as the insulator 152. The insulator 142 preferably functions as an etching stopper at the time of forming the opening in the insulator 150 and is formed using an insulator that can be used as the insulator 212.

The shape of the opening formed in the insulator 150 and the insulator 142 when seen from above may be a quadrangular shape, a polygonal shape other than a quadrangular shape, a polygonal shape with rounded corners, or a circular shape including an elliptical shape. Here, the area where the opening and the transistor 200 overlap with each other is preferably large in the top view. Such a structure can reduce the area occupied by the storage device including the capacitor 100 and the transistor 200.

The conductor 115 is placed in contact with the opening formed in the insulator 142 and the insulator 150. The top surface of the conductor 115 is preferably substantially level with the top surface of the insulator 142. Furthermore, the bottom surface of the conductor 115 is in contact with the conductor 110 through an opening in the insulator 130. The conductor 115 is preferably deposited by an ALD method, a CVD method, or the like; for example, a conductor that can be used as the conductor 205 is used.

The insulator 145 is placed to cover the conductor 115 and the insulator 142. The insulator 145 is preferably deposited by an ALD method or a CVD method, for example. The insulator 145 can be provided to have stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 145, an insulating film in which zirconium oxide, aluminum oxide, and zirconium oxide are stacked in this order can be used, for example.

As the insulator 145, a material with high dielectric strength, such as silicon oxynitride, or a high dielectric constant (high-k) material is preferably used. Alternatively, a stacked-layer structure of a material with high dielectric strength and a high dielectric constant (high-k) material may be used.

Examples of the high dielectric constant (high-k) material (a material having a high relative dielectric constant) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. The use of such a high-k material can ensure sufficient capacitance of the capacitor 100 even when the insulator 145 has a large thickness. When the insulator 145 has a large thickness, generation of a leakage current between the conductor 115 and the conductor 125 can be inhibited.

Examples of the material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which silicon nitride (SiNx) deposited by a PEALD method, silicon oxide (SiOx) deposited by a PEALD method, and silicon nitride (SiNx) deposited by a PEALD method are stacked in this order. Alternatively, an insulating film in which zirconium oxide, silicon oxide deposited by an ALD method, and zirconium oxide are stacked in this order can be used. The use of such an insulator with high dielectric strength can increase the dielectric strength and inhibit electrostatic breakdown of the capacitor 100.

The conductor 125 is placed to fill the opening formed in the insulator 142 and the insulator 150. The conductor 125 is electrically connected to the wiring 1005 through a conductor 140 and a conductor 153. The conductor 125 is preferably deposited by an ALD method, a CVD method, or the like and may be formed using a conductor that can be used as the conductor 205, for example.

The conductor 153 is provided over an insulator 154 and is covered with an insulator 156. The conductor 153 can be formed using a conductor that can be used as the conductor 112, and the insulator 156 can be formed using an insulator that can be used as the insulator 152. Here, the conductor 153 is in contact with the top surface of the conductor 140 and functions as a terminal of the capacitor 100, the transistor 200, or the transistor 300.

At least part of the structure, method, and the like described in this embodiment can be implemented in appropriate combination with any of those in the other embodiments, the other examples, and the like described in this specification.

### Embodiment 3

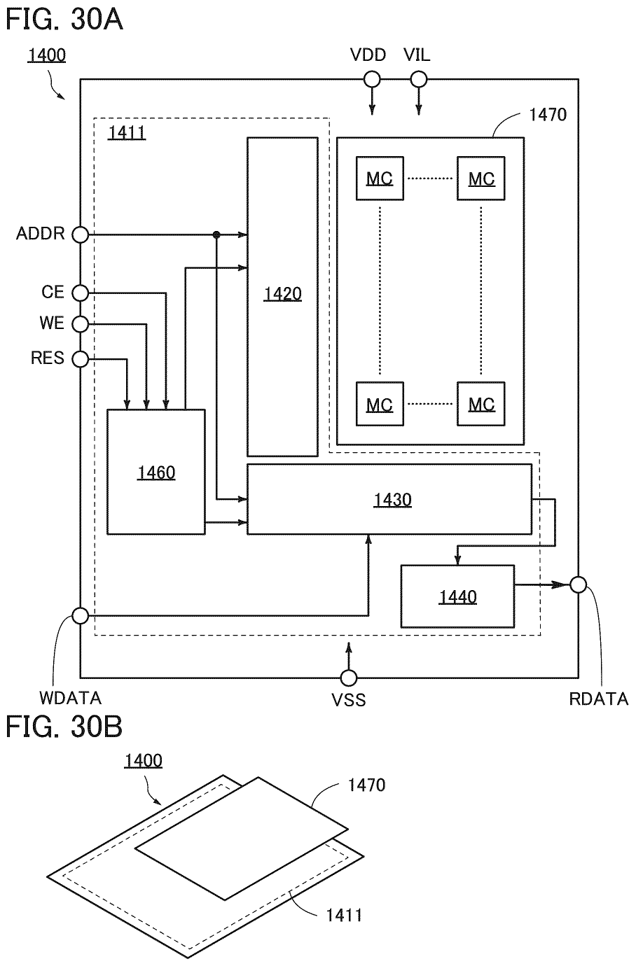

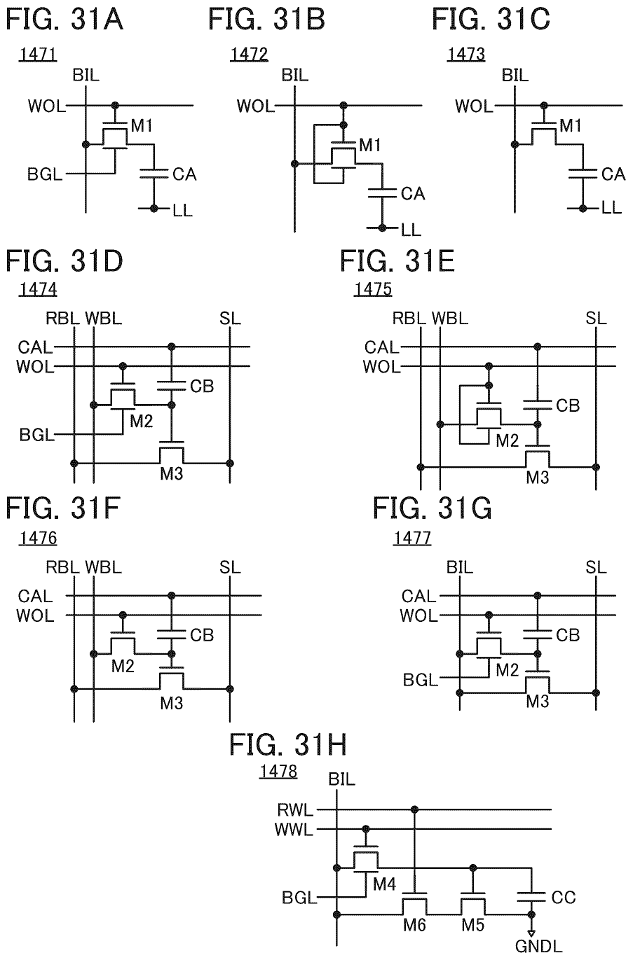

In this embodiment, a storage device including a transistor in which an oxide is used as a semiconductor (hereinafter, sometimes referred to as an OS transistor) and a capacitor (hereinafter, sometimes referred to as an OS memory apparatus) of one embodiment of the present invention will be described with reference to FIG. 30A, FIG. 30B, and FIG. 31A to FIG. 31H. The OS memory apparatus is a storage device that includes at least a capacitor and an OS transistor that controls the charging and discharging of the capacitor. Since the OS transistor has an extremely low off-state current, the OS memory apparatus has excellent retention characteristics and thus can function as a nonvolatile memory.

### <Structure Example of Storage Device>

FIG. 30A illustrates a structure example of the OS memory apparatus. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 30A illustrates an example where the peripheral circuit 1411 and the memory cell array 1470 are formed on the same plane; however, this embodiment is not limited to the example. For example, as illustrated in FIG. 30B, the memory cell array 1470 may be provided to overlap with part of the peripheral circuit 1411. For example, the sense amplifier may be provided below the memory cell array 1470 so that they overlap with each other.

FIG. 31A to FIG. 31H illustrate structure examples of a memory cell that can be used as the memory cell MC.

### [DOSRAM]

FIG. 31A to FIG. 31C illustrate circuit structure examples of a memory cell of a DRAM. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 31A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In the time of data writing and data reading, the wiring LL may be at a ground potential or a low-level potential. The wiring BGL functions as a wiring for applying a potential to the back gate of the transistor M1. When a given potential is applied to the wiring BGL, the threshold voltage of the transistor M1 can be increased or decreased.

Here, in the memory cell 1471 illustrated in FIG. 31A, the transistor M1 corresponds to the transistor 10 or the transistor 200 described in the above embodiment, and the capacitor CA corresponds to the capacitor 100 described in the above embodiment.

The circuit structure of the memory cell MC is not limited to that of the memory cell 1471, and the circuit structure can be changed. For example, as in a memory cell 1472 illustrated in FIG. 31B, the back gate of the transistor M1 may be connected not to the wiring BGL but to the wiring WOL in the memory cell MC. Alternatively, for example, the transistor M1 may be a single-gate transistor, that is, a transistor without a back gate in the memory cell MC as in a memory cell 1473 illustrated in FIG. 31C.

In the case where the semiconductor device described in any of the above embodiments is used in the memory cell 1471 and the like, the transistor 10 or the transistor 200 can be used as the transistor M1 described in the above embodiment, and the capacitor 100 can be used as the capacitor CA described in the above embodiment. When an OS transistor is used as the transistor M1, the off-state current of the transistor M1 can be extremely low. That is, with the use of the transistor M1, written data can be retained for a long time, and thus the frequency of the refresh operation for the memory cell can be decreased. Alternatively, refresh operation for the memory cell can be unnecessary. In addition, since the transistor M1 has an extremely low off-state current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 31D to FIG. 31G each illustrate a circuit structure example of a gain-cell memory cell including two transistors and one capacitor. A memory cell 1474 illustrated in FIG. 31D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing and data reading, a high-level potential is preferably applied to the wiring CAL. In the time of data retaining, a low-level potential is preferably applied to the wiring CAL. The wiring BGL functions as a wiring for applying a potential to the back gate of the transistor M2. The threshold voltage of the transistor M2 can be increased or decreased by applying a given potential to the wiring BGL.

Here, the memory cell 1474 illustrated in FIG. 31D corresponds to the storage device illustrated in FIG. 28 and FIG. 29. That is, the transistor M2 corresponds to the transistor 10 or the transistor 200 described in the above embodiment; the capacitor CB corresponds to the capacitor 100 described in the above embodiment; the transistor M3 corresponds to the transistor 300 described in the above embodiment; the wiring WBL corresponds to the wiring 1003 described in the above embodiment; the wiring WOL corresponds to the wiring 1004 described in the above embodiment; the wiring BGL corresponds to the wiring 1006 described in the above embodiment; the wiring CAL corresponds to the wiring 1005 described in the above embodiment; the wiring

RBL corresponds to the wiring 1002 described in the above embodiment; and the wiring SL corresponds to the wiring 1001 described in the above embodiment.

The circuit structure of the memory cell MC is not limited to that of the memory cell 1474 and can be changed as appropriate. For example, as in a memory cell 1475 illustrated in FIG. 31E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 31F. For example, the memory cell MC may have a structure in which the wiring WBL and the wiring RBL are combined into one wiring BIL as in a memory cell 1477 illustrated in FIG. 31G.

In the case where the semiconductor device described in any of the above embodiments is used in the memory cell 1474 and the like, the transistor 10 or the transistor 200 described in the above embodiment can be used as the transistor M2, the transistor 300 described in the above embodiment can be used as the transistor M3, and the capacitor 100 described in the above embodiment can be used as the capacitor CB. When an OS transistor is used as the transistor M2, the off-state current of the transistor M2 can be extremely low. Consequently, with the use of the transistor M2, written data can be retained for a long time, and thus the frequency of the refresh operation for the memory cell can be decreased. Alternatively, refresh operation for the memory cell can be unnecessary. In addition, since the transistor M2 has an extremely low off-state current, multi-level data or analog data can be retained in the memory cell 1474. The same applies to the memory cell 1475 to the memory cell 1477.

Note that the transistor M3 may be a transistor containing silicon in a channel formation region (hereinafter, sometimes referred to as a Si transistor). The conductivity type of the Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When an OS transistor is used as each of the transistor M2 and the transistor M3, the circuit of the memory cell array 1470 can be formed using only n-channel transistors.

FIG. 31H illustrates an example of a gain-cell memory cell including three transistors and one capacitor. A memory cell 1478 illustrated in FIG. 31H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In this case, the circuit of the memory cell array 1470 can be formed using only n-channel transistors.

In the case where the semiconductor device described in any of the above embodiments is used in the memory cell 1478, the transistor 10 or the transistor 200 described in the above embodiment can be used as the transistor M4, the transistor 300 described in the above embodiment can be used as the transistor M5 and the transistor M6, and the capacitor 100 described in the above embodiment can be used as the capacitor CC. When an OS transistor is used as the transistor M4, the off-state current of the transistor M4 can be extremely low.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

The structure, method, and the like described in this embodiment can be used in an appropriate combination with any of other structures, methods, and the like described in this embodiment or the other embodiments.

### Embodiment 4

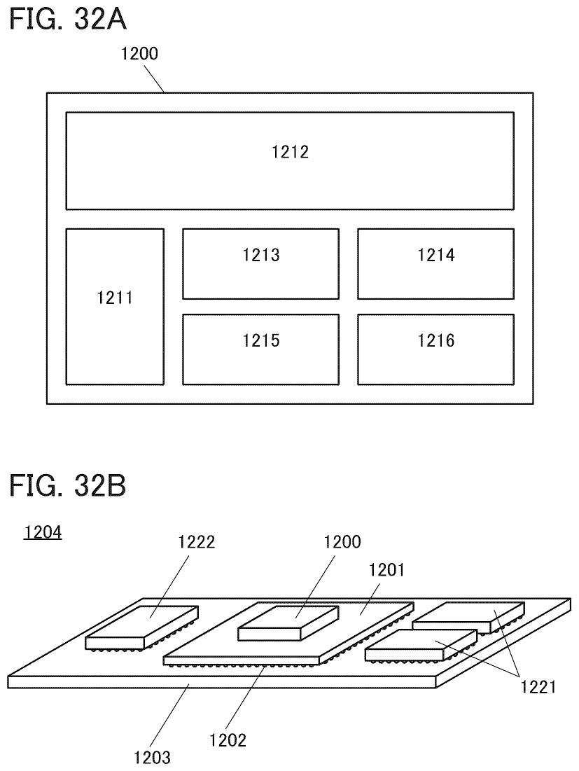

In this embodiment, an example of a chip 1200 on which the semiconductor device of the present invention is mounted is described with reference to FIG. 32A and FIG. 32B. A plurality of circuits (systems) are mounted on the chip 1200. A technique for integrating a plurality of circuits (systems) into one chip is referred to as system on chip (SoC) in some cases.

As illustrated in FIG. 32A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 32B, the chip 1200 is connected to a first surface of a package board 1201. In addition, a plurality of bumps 1202 are provided on a rear side of the first surface of the package board 1201, and the package board 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit including an oxide semiconductor of the present invention is provided in the GPU 1212, image processing or product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package board 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of those in the other embodiments and the other examples described in this specification.

### Embodiment 5

In this embodiment, examples of electronic components and electronic appliances in which the storage device or the like described in the above embodiment is incorporated are described.

### <Electronic Component>

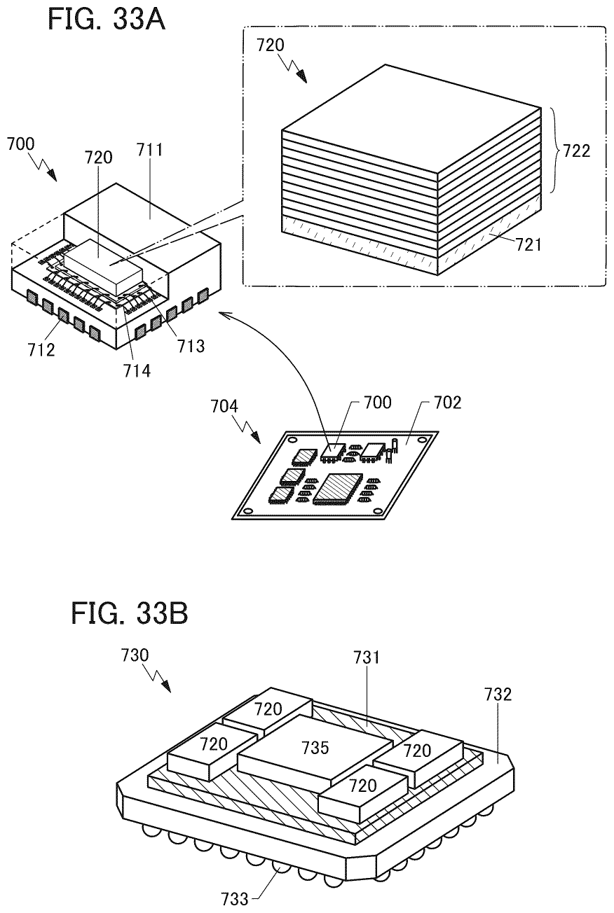

First, examples of an electronic component including a storage device 720 are described with reference to FIG. 33A and FIG. 33B.

FIG. 33A is a perspective view of an electronic component 700 and a substrate (a mounting board 704) on which the electronic component 700 is mounted. The electronic component 700 illustrated in FIG. 33A includes the storage device 720 in a mold 711. FIG. 33A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a storage circuit layer 722.

FIG. 33B is a perspective view of an electronic component 730. The electronic component 730 is an example of a SiP (System in package) or an MCM (Multi Chip Module). In the electronic component 730, an interposer 731 is provided over a package board 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package board 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package board 732. Accordingly, the interposer is sometimes referred to as a “redistribution substrate” or an “intermediate substrate”. A through electrode may be provided in the interposer 731 to be used for electrically connecting the integrated circuit and the package board 732. In the case of using a silicon interposer, a through-silicon via (TSV) can also be used as the through electrode.

A silicon interposer is preferably used as the interposer 731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth.

Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package board 732 to mount the electronic component 730 on another substrate. FIG. 33B illustrates an example where the electrode 733 is formed of a solder ball. Solder balls are provided in a matrix on the bottom portion of the package board 732, whereby a BGA (Ball Grid Array) mounting can be achieved. Alternatively, the electrode 733 may be formed of a conductive pin. When conductive pins are provided in a matrix on the bottom portion of the package board 732, a PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or the other embodiments.

### Embodiment 6

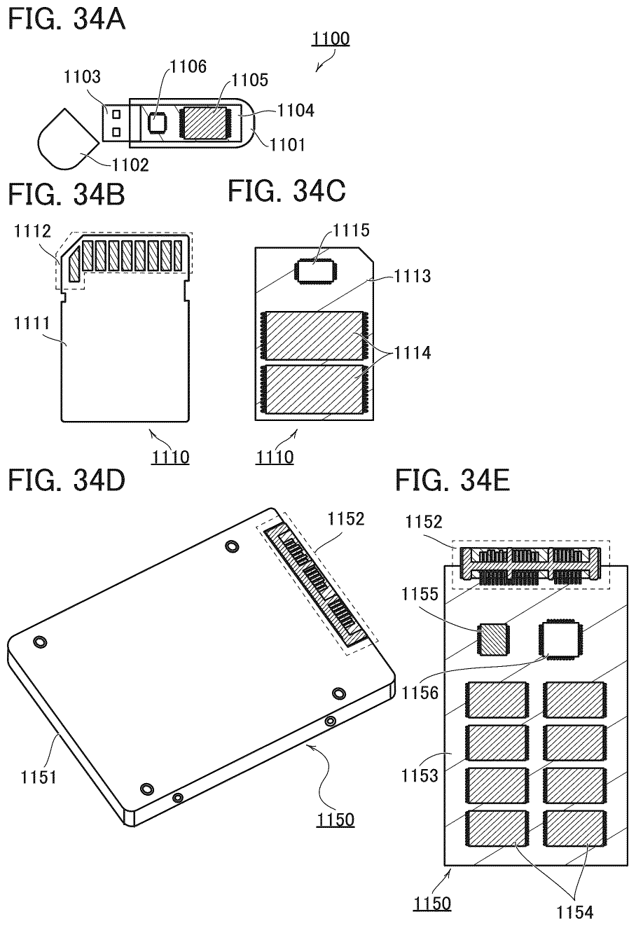

In this embodiment, application examples of the storage device using the semiconductor device described in the above embodiment are described. The semiconductor device described in the above embodiment can be applied to, for example, storage devices of a variety of electronic appliances (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 34A to FIG. 34E schematically illustrate some structure examples of removable storage devices. The semiconductor device described in the above embodiment is processed into a packaged memory chip and used in a variety of storage devices and removable memories, for example.

FIG. 34A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 34B is a schematic external view of an SD card, and FIG. 34C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a wireless communication function may be provided on the substrate 1113. This enables data reading and writing of the memory chip 1114 by wireless communication between a host device and the SD card 1110. The semiconductor device described in the above embodiment can be incorporated in the memory chip 1114 or the like.

FIG. 34D is a schematic external view of an SSD, and FIG. 34E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example.

The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like.

At least part of the structure, method, and the like described in this embodiment can be implemented in appropriate combination with any of those in the other embodiments and the other examples described in this specification.

### Embodiment 7

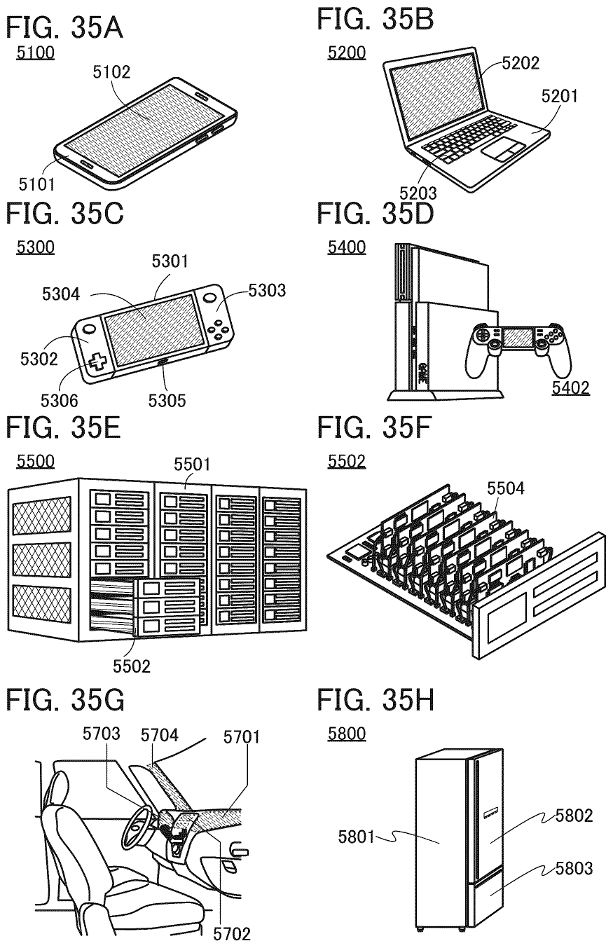

The semiconductor device of one embodiment of the present invention can be used as a processor such as a CPU and a GPU or a chip. FIG. 35A to FIG. 35H illustrate specific examples of electronic appliances including a chip or a processor such as a CPU or a GPU of one embodiment of the present invention.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 35A to FIG. 35H illustrate examples of electronic appliances.

### [Information Terminal]

FIG. 35A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 35B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 35A and FIG. 35B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 35C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 35D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 35C and FIG. 35D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 35E illustrates a supercomputer 5500 as an example of a large computer. FIG. 35F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 35E and FIG. 35F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 35G illustrates an area around a windshield inside an automobile, which is an example of a moving vehicle. FIG. 35G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile. That is, displaying an image taken by the imaging device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 35H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in appropriate combination with any of those in the other embodiments and the other examples described in this specification.

### REFERENCE NUMERALS

10A: transistor, 10a: transistor, 10B: transistor, 10b: transistor, 10c: transistor, 10d: transistor, 10: transistor, 16: insulator, 20: insulator, 22: insulator, 25a: conductor, 25b: conductor, 25: conductor, 30a: oxide, 30b: oxide, 30B: oxide film, 30i: region, 30n1: region, 30n2: region, 30: oxide, 35a: insulator, 35A: insulating film, 35b: insulator, 35: insulator, 36: insulator, 42a: conductor, 42A: conductive layer, 42b: conductor, 42B: conductive layer, 45a: conductor, 45b: conductor, 46a: conductor, 46b: conductor, 47a: insulator, 47b: insulator, 50a: insulator, 50A: insulating film, 50b: insulator, 50c: insulator, 50: insulator, 60a: conductor, 60A: conductive film, 60b: conductor, 60: conductor, 65: sealing portion, 74: insulator, 80: insulator, 83: insulator, 85: insulator, 100: capacitor, 110: conductor, 112: conductor, 115: conductor, 120: conductor, 125: conductor, 130: insulator, 140: conductor, 142: insulator, 145: insulator, 150: insulator, 152: insulator, 153: conductor, 154: insulator, 156: insulator, 200: transistor, 205: conductor, 210: insulator, 212: insulator, 216: insulator, 217: insulator, 218: conductor, 222: insulator, 230: oxide, 240: conductor, 241: insulator, 274: insulator, 280: insulator, 283: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 400: opening region, 500: semiconductor device, 700: electronic component, 702: printed circuit board, 704: mounting board, 711: mold, 712: land, 713: electrode pad, 714: wire, 720: storage device, 721: driver circuit layer, 722: storage circuit layer, 730: electronic component, 731: interposer, 732: package board, 733: electrode, 735: semiconductor device, 1001: wiring, 1002: wiring, 1003: wiring, 1004: wiring, 1005: wiring, 1006: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package board, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2700: manufacturing apparatus, 2701: atmosphere-side substrate supply chamber, 2702: atmosphere-side substrate transfer chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising a first transistor comprising:
a first metal oxide comprising a first depressed portion, a second depressed portion, and a third depressed portion between the first depressed portion and the second depressed portion;
a first conductor in the first depressed portion;
a second conductor in the second depressed portion;
a first insulator in the third depressed portion and over the first metal oxide; and
a third conductor over the first insulator, the third conductor overlapping with the first metal oxide with the first insulator therebetween,
wherein a top surface of the first conductor and a top surface of the second conductor are each level with or substantially level with a top surface of the first metal oxide.

2. A semiconductor device comprising a first transistor and a second transistor adjacent to each other,
the first transistor comprising:
a first metal oxide comprising a first depressed portion, a second depressed portion, and a third depressed portion between the first depressed portion and the second depressed portion;
a first conductor in the first depressed portion;
a second conductor in the second depressed portion;
a first insulator in the third depressed portion and over the first metal oxide; and
a third conductor over the first insulator, the third conductor overlapping with the first metal oxide with the first insulator therebetween,
wherein the first metal oxide of the first transistor and a second metal oxide of the second transistor are over a second insulator,
wherein a third insulator is over the first metal oxide and the second metal oxide and comprises an opening portion overlapping with the third depressed portion,
wherein the first insulator and the third conductor are in the opening portion of the third insulator,
wherein a fourth insulator is between the first metal oxide and the second metal oxide in a top view of the semiconductor device, and
wherein a top surface of the first conductor, a top surface of the second conductor, and a top surface of the first metal oxide are each level with or substantially level with a top surface of the fourth insulator.

3. The semiconductor device according to claim 1,
wherein a bottom surface of the first depressed portion is closer to a bottom surface side of the first metal oxide than a bottom surface of the third depressed portion, and
wherein a bottom surface of the second depressed portion is closer to a bottom surface side of the first metal oxide than the bottom surface of the third depressed portion.

4. The semiconductor device according to claim 1,
wherein a bottom surface of the first depressed portion is level with or substantially level with a bottom surface of the third depressed portion, and
wherein a bottom surface of the second depressed portion is level with or substantially level with the bottom surface of the third depressed portion.

5. The semiconductor device according to claim 1,
wherein a bottom surface of the first depressed portion is closer to a top surface side of the first metal oxide than a bottom surface of the third depressed portion, and
wherein a bottom surface of the second depressed portion is closer to a top surface side of the first metal oxide than the bottom surface of the third depressed portion.

6. A semiconductor device comprising a first transistor comprising:
a first metal oxide comprising a first depressed portion, a second depressed portion, and a third depressed portion between the first depressed portion and the second depressed portion;
a first conductor in the first depressed portion;
a second conductor in the second depressed portion;
a first insulator in the third depressed portion and over the first metal oxide; and
a third conductor over the first insulator, the third conductor overlapping with the first metal oxide with the first insulator therebetween,
wherein the first metal oxide is over a second insulator,
wherein a third insulator is over the first metal oxide and comprises an opening portion overlapping with the third depressed portion,
wherein the first insulator and the third conductor are in the opening portion of the third insulator,
wherein the first metal oxide is surrounded by a fourth insulator in a top view of the semiconductor device, and
wherein a top surface of the first conductor, a top surface of the second conductor, and a top surface of the first metal oxide are each level with or substantially level with a top surface of the fourth insulator.

7. The semiconductor device according to claim 2,
wherein a bottom surface of the first depressed portion is closer to a bottom surface side of the first metal oxide than a bottom surface of the third depressed portion, and
wherein a bottom surface of the second depressed portion is closer to a bottom surface side of the first metal oxide than the bottom surface of the third depressed portion.

8. The semiconductor device according to claim 2,
wherein a bottom surface of the first depressed portion is level with or substantially level with a bottom surface of the third depressed portion, and
wherein a bottom surface of the second depressed portion is level with or substantially level with the bottom surface of the third depressed portion.

9. The semiconductor device according to claim 2,
wherein a bottom surface of the first depressed portion is closer to a top surface side of the first metal oxide than a bottom surface of the third depressed portion, and
wherein a bottom surface of the second depressed portion is closer to a top surface side of the first metal oxide than the bottom surface of the third depressed portion.

10. The semiconductor device according to claim 3,
wherein a bottom surface of the first depressed portion is closer to a bottom surface side of the first metal oxide than a bottom surface of the third depressed portion, and
wherein a bottom surface of the second depressed portion is closer to a bottom surface side of the first metal oxide than the bottom surface of the third depressed portion.

11. The semiconductor device according to claim 3,
wherein a bottom surface of the first depressed portion is level with or substantially level with a bottom surface of the third depressed portion, and
wherein a bottom surface of the second depressed portion is level with or substantially level with the bottom surface of the third depressed portion.

12. The semiconductor device according to claim 3,
wherein a bottom surface of the first depressed portion is closer to a top surface side of the first metal oxide than a bottom surface of the third depressed portion, and
wherein a bottom surface of the second depressed portion is closer to a top surface side of the first metal oxide than the bottom surface of the third depressed portion.
